(19) United States
(12) Patent Application Publication
(10) Pub. No.: US 2024/0268113 A1
(43) Pub. Date: Aug. 8, 2024

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Sanghun CHUN, Suwon-si (KR); Jaehoon LEE, Suwon-si (KR); Kyung Taek CHO, Suwon-si (KR); Donghyuck JANG, Suwon-si (KR); Jeehoon HAN, Suwon-si (KR)

(21) Appl. No.: 18/229,560

(22) Filed: Aug. 2, 2023

(30) Foreign Application Priority Data
Feb. 8, 2023 (KR) 10-2023-0016852

(51) Int. Cl. H10B 43/27; H10B 43/40

(52) U.S. Cl. CPC H10B 43/27; H10B 43/40

(57) ABSTRACT

A semiconductor device includes a circuit region, a peripheral circuit structure on a first substrate; a cell region on the circuit region, a cell array region and connection region, the cell region including a second substrate; gate stacking structure on the second substrate, a lower structure, upper structures including gate electrodes; a channel structure penetrating the gate stacking structure; a gate contact penetrating the gate stacking structure electrically connected to the circuit region, and to a connection gate electrode insulated from a gate electrode by an insulating pattern between the gate electrode and the gate contact; a boundary insulating pattern partially formed in a boundary gate electrode among the gate electrodes of the lower structure adjacent to a boundary portion between the upper and lower structure surrounding the gate contact to maintain an electrical connection path of the boundary gate electrode and having a different structure from the insulating pattern.

### CROSS-REFERENCE TO RELATED APPLICATION

This application claims priority to and the benefit of Korean Patent Application No. 10-2023-0016852 filed in the Korean Intellectual Property Office on Feb. 8, 2023, the entire contents of which are incorporated herein by reference.

### BACKGROUND

### 1. Field

The present disclosure relates to a semiconductor device and an electronic system including the same.

### 2. Description of the Related Art

In an electronic system requiring data storage, a semiconductor device capable of storing high-capacity data is desired. Accordingly, a method for increasing a data storage capacity of the semiconductor device is being studied. For example, the semiconductor device including a three-dimensionally disposed memory cell instead of a two-dimensionally disposed memory cell has been proposed as a method for increasing the data storage capacity of the semiconductor device.

### SUMMARY

Embodiments are directed to a semiconductor device including a first substrate, a circuit region including a peripheral circuit structure on the first substrate; and a cell region that is disposed on the circuit region and includes a cell array region and a connection region, wherein the cell region includes a second substrate; a gate stacking structure that is disposed on the second substrate and includes a lower structure and an upper structure, wherein the lower structure and the upper structure each include a plurality of gate electrodes; a channel structure penetrating the gate stacking structure; a gate contact portion that penetrates the gate stacking structure to be electrically connected to the circuit region and that is electrically connected to a connection gate electrode among the plurality of gate electrodes, and is insulated from a remaining gate electrode by an insulating pattern that is disposed between the remaining gate electrode and the gate contact portion; and a boundary insulating pattern that is partially formed in a boundary gate electrode among the plurality of gate electrodes of the lower structure adjacent to a boundary portion between the upper structure and the lower structure to surround the gate contact portion to maintain an electrical connection path of the boundary gate electrode and has a different structure from that of the insulating pattern

A semiconductor device according to an embodiment may include: a circuit region including a peripheral circuit structure on a first substrate; and a cell region that is disposed on the circuit region and includes a cell array region and a connection region. The cell region may include a second substrate; a gate stacking structure that is disposed on the second substrate and a lower structure and an upper structure each including a plurality of gate electrodes; a channel structure penetrating the gate stacking structure; a gate contact portion that penetrates the gate stacking structure to be electrically connected to the circuit region, is electrically connected to a connection gate electrode among the plurality of gate electrodes, and is insulated from a remaining gate electrode by an insulating pattern being disposed between the remaining gate electrode and the gate contact portion; and a boundary insulating pattern that is partially formed in a boundary gate electrode among the plurality of gate electrodes of the lower structure adjacent to a boundary portion between the upper structure and the lower structure to surround the gate contact portion to maintain an electrical connection path of the boundary gate electrode and has a different structure from that of the insulating pattern.

A semiconductor device according to another embodiment includes: a circuit region including a peripheral circuit structure on a first substrate; and a cell region that is disposed on the circuit region and includes a cell array region and a connection region. The cell region includes a second substrate; a gate stacking structure that is disposed on the second substrate and includes a lower structure and an upper structure each including a plurality of gate electrodes; a channel structure penetrating the gate stacking structure; a gate contact portion that penetrates the gate stacking structure to be electrically connected to the circuit region; and a boundary insulating pattern that is partially formed in a boundary gate electrode among the plurality of gate electrodes of the lower structure adjacent to a boundary portion between the upper structure and the lower structure to surround the gate contact portion to maintain an electrical connection path of the boundary gate electrode, An entire side surface of the boundary insulating pattern includes an inclined surface gradually decreasing in width toward the second substrate or a vertical surface perpendicular to the second substrate when the boundary insulating pattern is viewed in a cross-section.

An electronic system according to an embodiment may include a main substrate; the semiconductor device on the main substrate; and a controller electrically connected to the semiconductor device on the main substrate.

According to an embodiment, a boundary insulating pattern may be provided so that a gate contact portion and a boundary gate electrode are separated while having a sufficient physical and electrical separation distance even if the gate contact portion falls out at a boundary portion. Accordingly, it is possible to fundamentally prevent the gate contact portion from damaging the boundary gate electrode at the boundary portion. In this case, since the boundary insulating pattern is partially formed at the boundary gate electrode, an electrical connection path may be maintained as it is. Accordingly, the boundary insulating pattern may be formed regardless of a disposition or the like of the plurality of pad areas.

Accordingly, productivity and reliability of a semiconductor device may be improved.

### BRIEF DESCRIPTION OF THE DRAWINGS

Features will become apparent to those of skill in the art by describing in detail exemplary embodiments with reference to the attached drawings in which:

FIG. 1 is a partial plan view illustrating a semiconductor device according to an embodiment.

FIG. 2 is a partial cross-sectional view of the semiconductor device taken along cut lines A-A′, B-B′, and C-C′ of FIG. 1.

FIG. 3 is a partial cross-sectional view illustrating an example of a channel structure included in the semiconductor device illustrated in FIG. 1.

FIG. 4 is a partial cross-sectional view of the semiconductor device taken along a cut line D-D′ of FIG. 1.

FIG. 5 is a partial plan view illustrating an upper surface of a second gate stacking structure in the semiconductor device illustrated in FIG. 1.

FIG. 6 is an enlarged view of portions E and F of FIG. 5.

FIG. 7 is an enlarged view of a portion G of FIG. 2.

FIGS. 8A to 8I are partial cross-sectional views illustrating a method for manufacturing the semiconductor device according to an embodiment.

FIG. 9 is an enlarged view of a portion of a lower structure of the semiconductor device according to another embodiment.

FIG. 10 is an enlarged view of a portion of a lower structure of the semiconductor device according to another embodiment.

FIG. 11 is a partial cross-sectional view of the semiconductor device according to another embodiment.

FIG. 12 is a partial cross-sectional view of the semiconductor device according to another embodiment.

FIG. 13 is a partial plan view illustrating an upper surface of a second gate stacking structure in a third lower pad area of the semiconductor device shown in FIG. 12.

FIG. 14 is a partial cross-sectional view of the semiconductor device according to another embodiment.

FIG. 15 is a partial cross-sectional view schematically illustrating the semiconductor device according to an additional embodiment.

FIG. 16 is a view schematically illustrating an electronic system including the semiconductor device according to an embodiment.

FIG. 17 is a schematic perspective view of an electronic system including the semiconductor device according to an embodiment.

FIG. 18 is a schematic cross-sectional view of a semiconductor package according to an embodiment.

FIG. 19 is a schematic cross-sectional view of a semiconductor package according to an embodiment.

### DETAILED DESCRIPTION

Further, throughout the specification, the phrase “in a plan view” or “on a plane” may refer to viewing a target portion from the top, and the phrase “in a cross-sectional view” or “on a cross-section” may refer to viewing a cross-section formed by vertically cutting a target portion from the side.

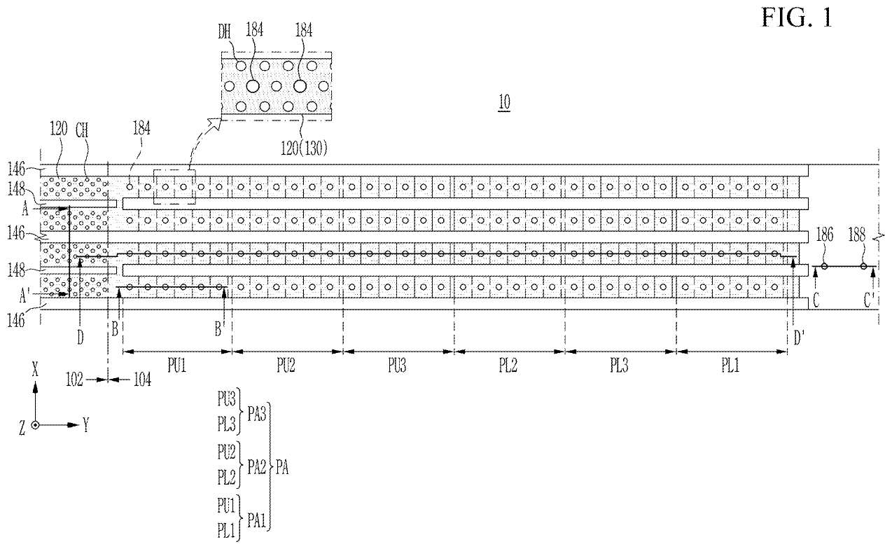

Hereinafter, a semiconductor device and a manufacturing method thereof according to an embodiment will be described in detail with reference to FIGS. 1 to 7 and FIGS. 8A to 8I.

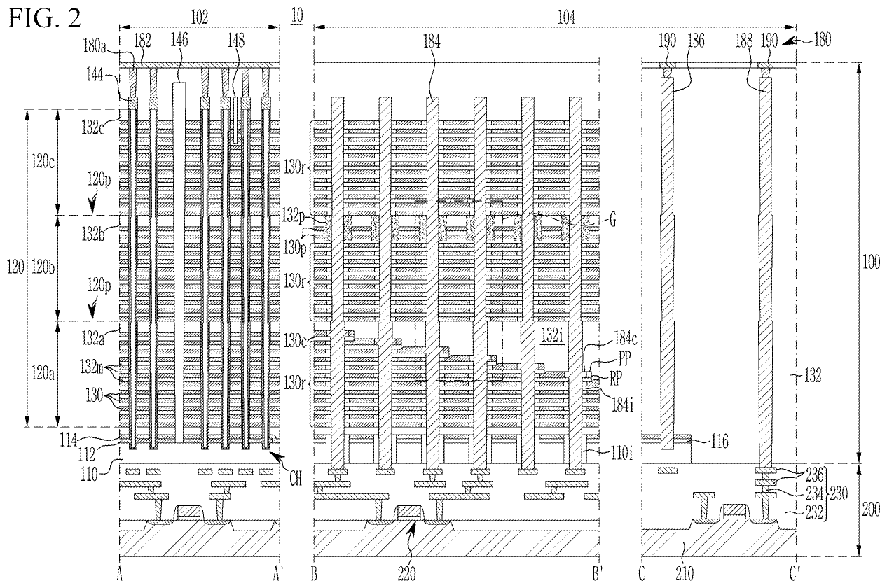

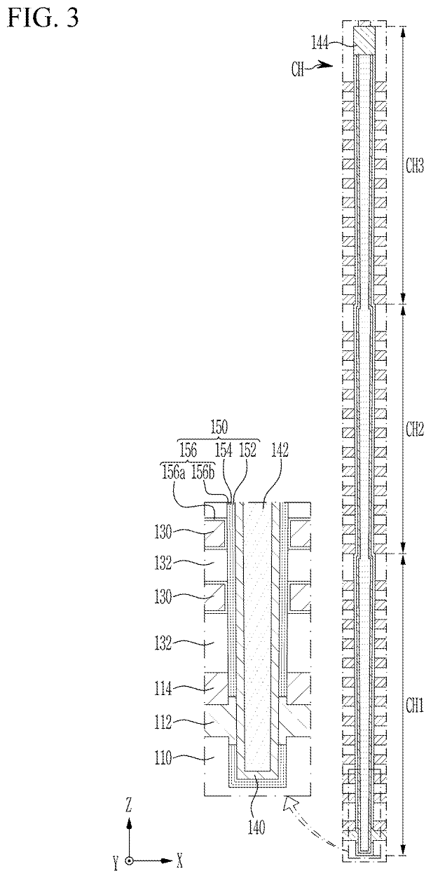

FIG. 1 is a partial plan view illustrating a semiconductor device according to an embodiment, and FIG. 2 is a partial cross-sectional view of the semiconductor device taken along cut lines A-A′, B-B′, and C-C′ of FIG. 1. FIG. 3 is a partial cross-sectional view illustrating an example of a channel structure included in the semiconductor device illustrated in FIG. 1.

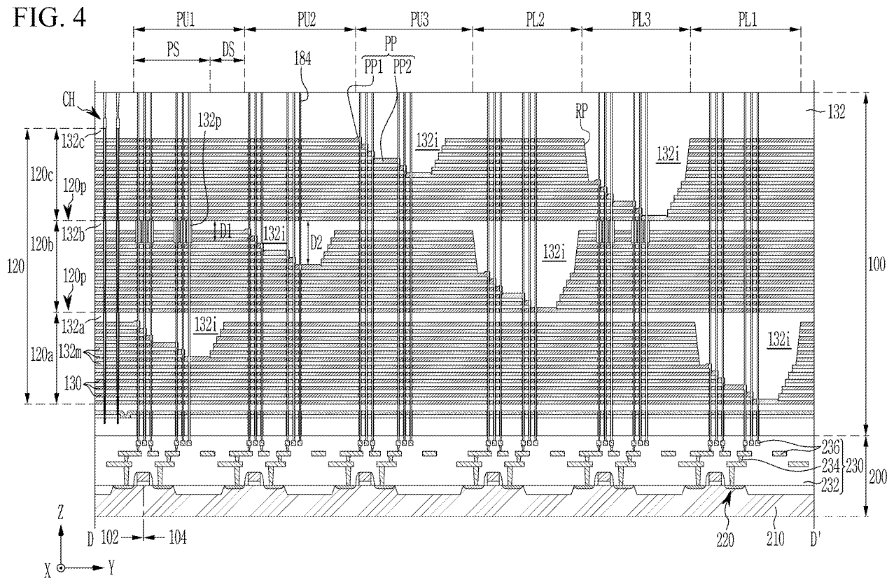

For simplicity and clear understanding, in FIG. 1, a second wire portion 180 may be omitted and a channel structure CH, a gate contact portion 184, and the like may be mainly shown. Two continuous dotted lines or solid lines in FIG. 1 may indicate a dummy section DS of FIG. 4 of each pad area PA. Further, for simplicity of illustration, a dummy structure DH may be shown only in an enlarged view, and may be not shown in a view other than the enlarged view. For simplicity of illustration, in a drawing other than FIG. 4, gaps between a plurality of gate contact portions 184 are shown to be the same.

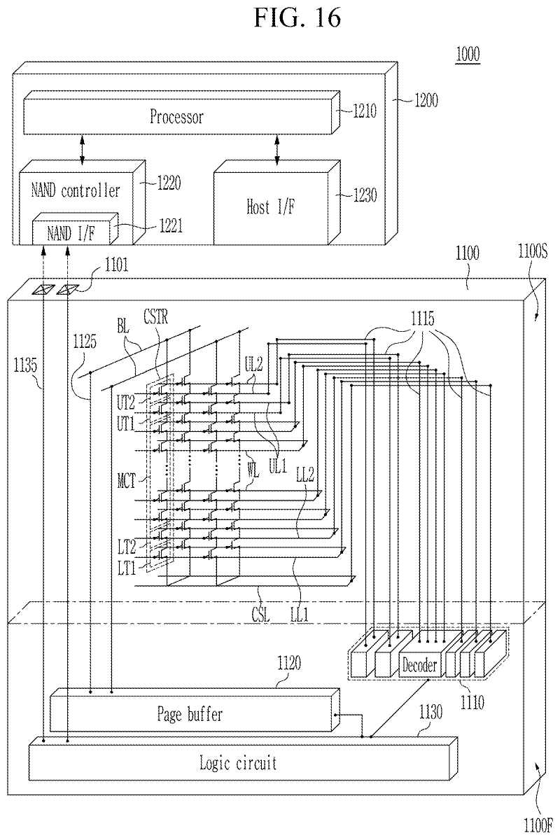

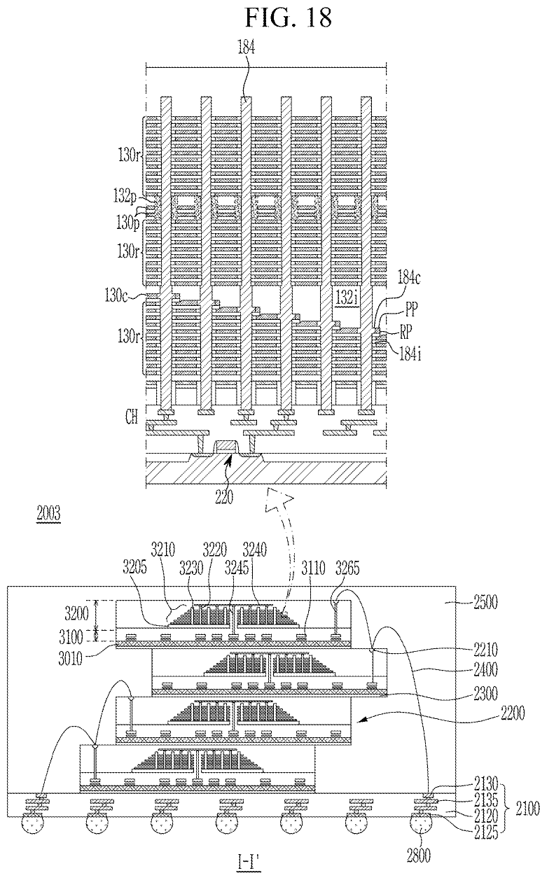

Referring to FIGS. 1 to 3, the semiconductor device 10 according to the embodiment may include a cell region 100 provided with a memory cell structure and a circuit region 200 provided with a peripheral circuit structure controlling an operation of the memory cell structure. For example, the circuit region 200 and the cell region 100 may be portions corresponding to a first structure 1100F and a second structure 1100S of a semiconductor device 1100 included in an electronic system 1000 shown in FIG. 16, respectively. In some implementations, the circuit region 200 and the cell region 100 may be portions including a first structure 3100 and a second structure 3200 of a semiconductor chip 2200 shown in FIG. 18, respectively.

Here, the circuit region 200 may include the peripheral circuit structure formed above or on a first substrate 210, and the cell region 100 may include a gate stacking structure 120 and the channel structure CH formed above or on a cell array region 102 of a second substrate 110 that are the memory cell structure. A first wire portion 230 may be provided in the circuit region 200, and the second wire portion 180 electrically connected to the memory cell structure may be provided in the cell region 100.

In an embodiment, the cell region 100 may be disposed above or on the circuit region 200. Accordingly, an area corresponding to the circuit region 200 does not need to be secured separately from the cell region 100. Therefore, an area of the semiconductor device 10 may be reduced. However, the embodiments are not limited thereto, and the circuit region 200 may be disposed next to the cell region 100. Various other variations are possible.

The circuit region 200 may include the first substrate 210, and a circuit element 220 and the first wire portion 230 formed above or on the first substrate 210.

The first substrate 210 may be a semiconductor substrate including a semiconductor material. For example, the first substrate 210 may be a semiconductor substrate made of a semiconductor material or may be a semiconductor substrate in which a semiconductor layer is formed on a base substrate. For example, the first substrate 210 may include a monocrystalline or polycrystalline silicon, an epitaxial silicon, germanium, silicon-germanium, a silicon on insulator (SOI), a germanium on insulator (GOI), or the like.

The circuit element 220 formed on the first substrate 210 may include any of various circuit elements that control an operation of the memory cell structure provided in the cell region 100. For example, the circuit element 220 may include peripheral circuit structures such as a decoder circuit 1110 of FIG. 16, a page buffer 1120 of FIG. 16), a logic circuit 1130 of FIG. 16, or the like.

For example, the circuit element 220 may include a transistor, as a non-limiting example. For example, the peripheral circuit element 220 may include not only an active element such as the transistor or the like but also a passive element such as a capacitor, a resistor, an inductor, or the like.

The first wire portion 230 disposed above or on the first substrate 210 may be electrically connected to the circuit element 220. In an embodiment, the first wire portion 230 may include a plurality of wire layers 236 that are spaced apart from a first insulating layer 232 disposed between the wire layers and form a desired path by a contact via 234. The wire layer 236 or the contact via 234 may include any of various conductive materials, and the first insulating layer 232 may include any of various insulating materials. For example, the wire layer 236 among the plurality of wire layers 236 disposed at an uppermost portion adjacent to the cell region 100 may include a pad portion to which the gate contact portion 184, a through plug 188, and the like are connected, or may constitute a pad portion.

The cell region 100 may include the cell array region 102 and a connection region 104. The gate stacking structure 120 and the channel structure CH may be formed above or on the second substrate 110 in the cell array region 102. A structure that connects the gate stacking structure 120 and/or the channel structure CH formed in the cell array region 102 to the circuit region 200 or an external circuit may be disposed in the cell array region 102 and/or the connection region 104.

In an embodiment, the second substrate 110 may include a semiconductor layer including a semiconductor material. For example, the second substrate 110 may be a semiconductor substrate made of a semiconductor material or may be a semiconductor substrate in which a semiconductor layer is formed on a base substrate. For example, the second substrate 110 may be formed of silicon, germanium, silicon-germanium, a silicon on insulator, a germanium on insulator, or the like. Here, a semiconductor layer included in the second substrate 110 may be doped with p-type or n-type impurities. For example, the semiconductor layer included in the second substrate 110 may be doped with an n-type impurity or dopant (e.g., phosphorus (P), arsenic (As), or the like). A substrate insulating portion 110i may be provided in a region through which the gate contact portion 184 passes in the second substrate 110, as a non-limiting example. In some implementations a conductive type of an impurity doped in the semiconductor layer, the material of the semiconductor layer, and the like may be provided.

The gate stacking structure 120 including cell insulating layers 132 and gate electrodes 130 alternately stacked on a first surface (e.g., a front surface or an upper surface) of the second substrate 110 and the channel structure CH extending in a direction crossing the second substrate 110 through the gate stacking structure 120 may be formed at the cell array region 102.

In an embodiment, horizontal conductive layers 112 and 114 may be provided between the second substrate 110 and the gate stacking structure 120 in the cell array region 102. The horizontal conductive layers 112 and 114 may serve to electrically connect the channel structure CH and the second substrate 110. For example, the horizontal conductive layers 112 and 114 may include a first horizontal conductive layer 112 disposed on the first surface of the second substrate 110, and may further include a second horizontal conductive layer 114 disposed on the first horizontal conductive layer 112. The first horizontal conductive layer 112 may be omitted and a horizontal insulating layer 116 may be provided between the second substrate 110 and the gate stacking structure 120 in a partial region of the connection region 104. In a manufacturing process, a portion of the horizontal insulating layer 116 may be replaced with the first horizontal conductive layer 112, and another portion of the horizontal insulating layer 116 disposed at the connection region 104 may remain at the connection region 104.

The first horizontal conductive layer 112 may function as a portion of a common source line of the semiconductor device 10. For example, the first horizontal conductive layer 112 may function as the common source line together with the second substrate 110. As shown in an enlarged view of FIG. 3, the channel structure CH may penetrate through the horizontal conductive layers 112 and 114 to extend to reach the second substrate 110, and a gate dielectric layer 150 may be removed from a portion where the first horizontal conductive layer 112 is disposed so that the first horizontal conductive layer 112 is directly connected to a channel layer 140 around the channel layer 140.

The first and second horizontal conductive layers 112 and 114 may include a semiconductor material (e.g., a polycrystalline silicon). For example, the first horizontal conductive layer 112 may be a polycrystalline silicon layer doped with an impurity or a dopant, and the second horizontal conductive layer 114 may be a polycrystalline silicon layer doped with an impurity or dopant or may be a layer including an impurity or dopant diffused from the first horizontal conductive layer 112, as non-limiting examples. In some implementations the second horizontal conductive layer 114 may be formed of an insulating material. In some implementations, the second horizontal conductive layer 114 may not be separately provided.

The gate stacking structure 120 in which the cell insulating layers 132 and the gate electrodes 130 are alternately stacked may be disposed above or on the second substrate 110 (e.g., on the first and second horizontal conductive layers 112 and 114 formed on the second substrate 110).

In an embodiment, the gate stacking structure 120 may include a plurality of gate stacking structures 120a, 120b, and 120c sequentially stacked above the second substrate 110. Then, when the number of stacked gate electrodes 130 is increased, the number of memory cells with a stable structure may be increased. As non-limiting examples, the gate stacking structure 120 may include the first to third gate stacking structures 120a, 120b, and 120c to increase a data storage capacity while simplifying a structure. In some implementations, the gate stacking structure 120 may include two or four or more gate stacking structures.

In the gate stacking structure 120, the gate electrode 130 may include a lower gate electrode, a memory cell gate electrode, and an upper gate electrode sequentially disposed above the second substrate 110. The lower gate electrode may be used as a gate electrode of a ground selection transistor, the memory cell gate electrode may constitute a memory cell, and the upper gate electrode may be used as a gate electrode of a string selection transistor. The number of memory cell gate electrodes may be determined according to a data storage capacity of the semiconductor device 10. According to an embodiment, one or two or more lower gate electrodes and one or two or more upper gate electrodes may be provided. Each of the gate electrode and the upper gate electrode may have the same structure as or a different structure from the memory cell gate electrode. Further, a portion (e.g., the memory cell gate electrode adjacent to the lower gate electrode and the upper gate electrode) of the gate electrode 130 may be a dummy gate electrode.

The cell insulating layer 132 may include an interlayer insulating layer 132m disposed between two adjacent gate electrodes 130 within the first to third gate stacking structures 120a, 120b, and 120c, and upper insulating layers 132a, 132b, and 132c disposed at an upper portion of the first to third gate stacking structures 120a, 120b, and 120c. Further, the cell insulating layer 132 may further include a pad insulating portion 132i formed while filling a recess portion RP provided in the pad area PA. The pad insulating portion 132i may form a portion of the upper insulating layers 132a, 132b, and 132c or may be provided separately from the upper insulating layers 132a, 132b, and 132c.

For example, the upper insulating layers 132a, 132b, and 132c may include the first to third upper insulating layers 132a, 132b, and 132c respectively disposed at upper portions of the first to third gate stacking structures 120a, 120b, and 120c. In this case, the first and second upper insulating layers 132a and 132b are intermediate insulating layers disposed between two neighboring gate stacking structures among the first to third gate stacking structures 120a, 120b, and 120c, and the third upper insulating layer 132c is an uppermost insulating layer disposed at an uppermost portion of the gate stacking structure 120. The third upper insulating layer 132c may constitute a portion or all of a cell region insulating layer disposed entirely at an upper portion of the cell region 100.

In an embodiment, thicknesses of a plurality of cell insulating layers 132 may not all be the same. For example, thicknesses of the upper insulating layers 132a, 132b, and 132c may be greater than a thickness of the interlayer insulating layer 132m. However, a shape, a structure, or the like of the cell insulating layer 132 may be variously modified according to an embodiment.

For simplicity of illustration, FIG. 2 illustrates that the cell insulating layer 132 is provided as one without a boundary at a portion where a source contact portion 186 and the through plug 188 are provided in the connection region 104. However, one or a plurality of insulating layers in the connection region 104 may have any of various stacking structures, as non-limiting embodiments.

The gate electrode 130 may include any of various conductive materials. For example, the gate electrode 130 may include a metal material such as tungsten (W), copper (Cu), aluminum (Al), or the like, a polycrystalline silicon, a metal nitride (e.g., titanium nitride (TiN), tantalum nitride (TaN), or the like), or a combination thereof. As shown in the enlarged view of FIG. 3, a portion (e.g., a first blocking layer 156a) of a blocking layer 156 formed of an insulating material may be disposed outside the gate electrode 130. The cell insulating layer 132 may include any of various insulating materials. For example, the cell insulating layer 132 may include a silicon oxide, a silicon nitride, a silicon oxynitride, a low dielectric constant material having a lower dielectric constant than the silicon oxide, or a combination thereof.

In an embodiment, the channel structure CH that penetrates the gate stacking structure 120 and extends in a direction (e.g., a vertical direction perpendicular to the second substrate 110 or a Z-axis direction in the drawings) crossing the second substrate 110, may be formed.

The channel structure CH may include the channel layer 140 and the gate dielectric layer 150 disposed on the channel layer 140 between the gate electrode 130 and the channel layer 140. The channel structure CH may further include a core insulating layer 142 disposed inside the channel layer 140, and may further include a channel pad 144 disposed on the channel layer 140 and/or the gate dielectric layer 150.

Each channel structure CH forms one memory cell string, and a plurality of channel structures CH may be spaced apart from each other while forming rows and columns on a plane. For example, a plurality of channel structures CH may be disposed in various shapes such as a lattice shape, a zigzag shape, and the like on a plane. The channel structure CH may have a pillar shape. For example, when the channel structure CH is viewed in a cross-section, the channel structure CH may have an inclined side surface so that a width of the channel structure becomes narrow as the channel structure is close to the second substrate 110 according to an aspect ratio, as a non-limiting embodiment. In some implementations, a disposition, a structure, a shape, or the like of the channel structure CH may be variously modified.

The core insulating layer 142 may be provided in a central region of the channel structure CH. The channel layer 140 may be formed while surrounding a sidewall of the core insulating layer 142. For example, the core insulating layer 142 may have a pillar shape (e.g., a cylindrical shape or a polygonal pillar shape). and the channel layer 140 may have a planar shape such as an annular shape or the like, as non-limiting embodiments. In some implementations, the core insulating layer 142 may not be provided, and the channel layer 140 may have a pillar shape (e.g., a cylindrical shape or a polygonal pillar shape).

As examples, the channel layer 140 may include a semiconductor material (e.g., a polycrystalline silicon). The core insulating layer 142 may include any of various insulating materials. The core insulating layer 142 may include a silicon oxide, a silicon nitride, a silicon oxynitride, or a combination thereof, as non-limiting examples, and The embodiment is not limited to materials of the channel layer 140 and the core insulating layer 142.

The gate dielectric layer 150 disposed between the gate electrode 130 and the channel layer 140 may include a tunneling layer 152, a charge storage layer 154, and a blocking layer 156 sequentially formed on the channel layer 140.

In this case, the tunneling layer 152 may be a layer in which a charge is tunneled according to a voltage applied to the gate electrode 130, and may include an insulating material capable of tunneling a charge. The tunneling layer 152 may include a material such as a silicon oxide, a silicon oxynitride, or the like. For example, the tunneling later 152 may be formed by stacking a silicon oxide film and a silicon nitride film.

The charge storage layer 154 disposed between the tunneling layer 152 and the blocking layer 156 may be used as a data storage region. For example, the charge storage layer 154 may include a silicon nitride capable of trapping a charge and may be formed of a silicon nitride film as a non-limiting example. When the charge storage layer 154 is formed of a silicon nitride, the charge storage layer having the silicon nitride may have excellent retention, which may be advantageous for integration compared with a charge storage layer having polycrystalline silicon.

The blocking layer 156 may be disposed between the charge storage layer 154 and the gate electrode 130. The blocking layer 156 may include an insulating material that is capable of preventing an undesirable flow of charge into the gate electrode 130. The blocking layer 156 may include, for example, a silicon oxide, a silicon nitride, a silicon oxynitride, a high dielectric constant material, or a combination thereof. Here, the term ‘high dielectric constant material’ may refer to a dielectric material having a higher dielectric constant than silicon oxide. For example, the high dielectric constant material may include aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), or a combination thereof, as non-limiting examples.

In an embodiment, the blocking layer 156 may include the first blocking layer 156a including a portion that extends horizontally along the gate electrode 130 and a second blocking layer 156b extending vertically between the first blocking layer 156a and the charge storage layer 154.

The channel pad 144 may be disposed on the channel layer 140 and/or on the gate dielectric layer 150. The channel pad 144 may be disposed to cover an upper surface of the core insulating layer 142 and to be electrically connected to the channel layer 140. For example, the channel pad 144 may include a conductive material (e.g., a polycrystalline silicon doped with an impurity), as non-limiting examples.

Accordingly, when the plurality of gate stacking structures 120a, 120b, and 120c are provided, the channel structure CH may include a plurality of channel structures CH1, CH2, and CH3 that respectively penetrate the plurality of gate stacking structures 120a, 120b, and 120c. In an embodiment, the plurality of channel structures CH may include the first to third channel structures CH1, CH2, and CH3 that respectively extend through the first to third gate stacking structures 120a, 120b, and 120c.

The first, second, and third channel structures CH1, CH2, and CH3 may have a shape so as to be connected to each other. When the first, second, and third channel structures CH1, CH2, and CH3 are viewed in a cross-section, each of the first, second, and third channel structures CH1, CH2, and CH3 may have an inclined side surface such that a width of each of the first, second, and third channel structures becomes narrower as the each of the first, second, and third channel structures become closer to the second substrate 110 according to an aspect ratio. As shown in FIG. 3, a bent portion may be provided due to a difference in widths of each of the first, second, and third channel structures at a portion where the first channel structure CH1 and the second channel structure CH2 are connected to each other and at a portion where the second channel structure CH2 and the third channel structure CH3 are connected to each other. As another example, the first, second, and third channel structures CH1, CH2, and CH3 may have an inclined side surface that is continuously connected without a bent portion. Thus, the embodiment may not be limited to shapes of the first, second, and third channel structures CH1, CH2, and CH3.

FIG. 3 illustrates that the gate dielectric layer 150, the channel layer 140, and the core insulating layer 142 of the first, second, and third channel structures CH1, CH2, and CH3 may have an integral structure extending from each other. After first to third penetration portions for the first to third channel structures CH1, CH2, and CH3 are formed, the above-described structure may be formed by forming the gate dielectric layer 150, the channel layer 140, and the core insulating layer 142 throughout the first to third penetration portions. In some implementations, the gate dielectric layer 150, the channel layer 140, and the core insulating layer 142 of the first, second, and third channel structures CH1, CH2, and CH3 may be separately formed to be electrically connected to each other. For example, after the first penetration portion for the first channel structure CH1 is formed, the gate dielectric layer 150, the channel layer 140, and the core insulating layer 142 may be formed at the first penetration portion, after the second penetration portion for the second channel structure CH2 is formed. The gate dielectric layer 150, the channel layer 140, and the core insulating layer 142 may be formed at the second penetration portion. After the third penetration portion for the third channel structure CH3 is formed, the gate dielectric layer 150, the channel layer 140, and the core insulating layer 142 may be formed at the third penetration portion. Other variations are possible.

In an embodiment, the channel pad 144 may be provided on the channel structure CH (e.g., the third channel structure CH3) provided in the gate stacking structure (e.g., the third gate stacking structure 120c) disposed at an upper portion of the plurality of gate stacking structures 120. In some implementations, channel pads 144 may be respectively provided on the first to third channel structures CH1, CH2, and CH3. In this case, the channel pad 144 of the first or second channel structures CH1 and CH2 may be connected to the channel layer 140 of the second or third channel structures CH2 and CH3 disposed at an upper portion.

In an embodiment, the gate stacking structure 120 may be divided into a plurality of portions on a plane by a separation structure 146 extending in a direction (e.g., a vertical direction perpendicular to the second substrate 110 or a Z-axis direction in the drawings) crossing the second substrate to pass through the gate stacking structure 120.

For example, the separation structure 146 may pass through the gate electrode 130 and the cell insulating layer 132 to extend to the second substrate 110. On a plane, the separation structure 146 may extend in a first direction or one direction (a Y-axis direction in the drawings), and a plurality of separation structures 146 may be provided to be spaced apart from each other at predetermined intervals in a second direction or a crossing direction (an X-axis direction in the drawings) crossing the one direction. Accordingly, on a plane, the plurality of gate stacking structures 120 may extend in one direction (the Y-axis direction in the drawings), and may be spaced apart from each other at predetermined intervals in a crossing direction (the X-axis direction in the drawings). The gate stacking structure 120 divided by the separation structure 146 may constitute one memory cell block, as a non-limiting example.

For example, when the separation structure 146 is viewed in a cross-section, the separation structure 146 may have an inclined side surface such that a width of the separation structure 146 is reduced while the separation structure faces the second substrate 110 due to a high aspect ratio, as a non-limiting example. In some implementations, a side surface of the separation structure 146 may be perpendicular to the second substrate 110. FIG. 2 illustrates that the separation structure 146 may have a continuous inclined side surface at the first to third gate stacking structures 120a, 120b, and 120c and may not include a bent portion when the separation structure 146 is viewed in a cross-section, as a non-limiting example. The separation structure 146 may include the bent portion at a boundary portion 120p of the first to third gate stacking structures 120a, 120b, and 120c.

The separation structure 146 may be filled with any of various insulating materials. For example, the separation structure 146 may include an insulating material such as a silicon oxide, a silicon nitride, or a silicon oxynitride, as non-limiting examples. A structure, a shape, a material, or the like of the separation structure 146 may be variously modified.

An upper separation region 148 may be formed at an upper portion of the gate stacking structure 120. On the plane, the upper separation region 148 may extend in one direction (a Y-axis direction in the drawings), and a plurality of upper separation regions 148 may be provided to be spaced apart from each other at predetermined intervals in a crossing direction (an X-axis direction in the drawings) crossing the one direction.

The upper separation region 148 may be formed through one or a plurality of gate electrodes 130 including an upper gate electrode disposed between the separation structures 146. For example, the upper separation region 148 may separate three gate electrodes 130 from each other in a crossing direction (the X-axis direction in the drawings), as a non-limiting example. Embodiments are not limited to the number of gate electrodes 130 separated by the upper separation region 148. The upper separation region 148 may have a shape that is filled with an insulating material. For example, the upper separation region 148 may include an insulating material such as a silicon oxide, a silicon nitride, or a silicon oxynitride, as non-limiting examples. A structure, a shape, a material, or the like of the upper separation region 148 may be variously modified.

The connection region 104 and the second wire portion 180 may be provided to connect the gate stacking structure 120 and the channel structure CH provided in the cell array region 102 to the circuit region 200 or an external circuit.

The second wire portion 180 may include a member electrically connecting the gate electrode 130, the channel structure CH, the horizontal conductive layers 112 and 114, and/or the second substrate 110 to the circuit region 200 or the external circuit. For example, the second wire portion 180 may include a bit line 182, the gate contact portion 184, the source contact portion 186, the through plug 188, a contact via 180a connected to each of the bit line 182, the gate contact portion 184, the source contact portion 186, and the through plug 188, and a connection wire 190 connecting the bit line 182, the gate contact portion 184, the source contact portion 186, and the through plug 188.

The bit line 182 may be disposed above or on the cell insulating layer 132 of the gate stacking structure 120 formed in the cell array region 102. The bit line 182 may extend in a crossing direction (an X-axis direction in the drawings) crossing one direction in which the gate electrode 130 extends. The bit line 182 may be electrically connected to the channel structure CH (e.g., the channel pad 144) through the contact via 180a (e.g., a bit line contact via).

The connection region 104 may be disposed around the cell array region 102, and a portion of the second wire portion 180 may be disposed at the connection region 104. The connection region 104 may include a member that connects the gate electrode 130, the horizontal conductive layers 112 and 114, the second substrate 110, and the circuit region 200. In addition, the connection region 104 may include a portion in which an input/output pad and an input/output connection wire are formed.

More specifically, the gate contact portion 184 may pass through the gate stacking structure 120 to be connected to the gate electrode 130, and may extend to a pad portion provided in the circuit region 200 to be electrically connected to the circuit region 200. A connection structure of the gate contact portion 184 and the gate electrode 130 will be described in more detail below. In the connection region 104, the source contact portion 186 may penetrate the cell insulating layer 132 to be electrically connected to the horizontal conductive layers 112 and 114 and/or to the second substrate 110. The through plug 188 may pass through the gate stacking structure 120 or may be disposed outside the gate stacking structure 120 to be electrically connected to the first wire portion 230 of the circuit region 200.

The dummy structure DH may be further provided in the connection region 104. The dummy structure DH may serve to reduce stress that may be applied to the gate stacking structure 120. The dummy structure DH may have the same or similar structure or shape as the channel structure CH, but is not electrically connected to the bit line 182. The dummy structure DH may be formed in the same process as the channel structure CH together with the channel structure CH to be formed of the same structure, shape, material, or the like, or may be formed in a process separate from the channel structure CH to have a different structure, shape, material, or the like from the channel structure CH. In an embodiment, the dummy structure DH may have a larger plane size than the channel structure CH. In the drawings, for example, a plurality of dummy structures DH may be disposed to have a hexagonal shape, and may be disposed inside the gate electrode 130, as a non-limiting example. In some implementations, at least a portion of the dummy structure DH may be disposed over the edge of the gate electrode 130 to contact the separation structure 146. Other variations are possible.

The connection wire 190 may be disposed at the cell array region 102 and/or the connection region 104. The bit line 182, the source contact portion 186, and/or the through plug 188 may be electrically connected to the connection wire 190. For example, the source contact portion 186 and/or the through plug 188 may be connected to the connection wire 190 through the contact via 180a. In an embodiment, when the contact via 180a and the connection wire 190 connected to the gate contact portion 184 are not provided, design freedom of the second wire portion 180 may be improved. According to an embodiment, the contact via 180a and the connection wire 190 connected to the gate contact portion 184 may be provided.

FIG. 2 illustrates that the connection wire 190 is provided as a single layer disposed on the same plane as the bit line 182 and a second insulating layer 192 is disposed on a portion other than the second wire portion 180. However, this is only briefly shown for convenience. In order for the connection wire 190 to make electrical connection with the bit line 182, the gate contact portion 184, the source contact portion 186, and/or the through plug 188, the connection wire 190 may include a plurality of wire layers, and may further include a contact via.

Thus, the bit line 182, the gate electrode 130, the horizontal conductive layers 112 and 114, and/or the second substrate 110 connected to the channel structure CH may be electrically connected to the circuit element 220 of the circuit region 200 by the second wire portion 180 and the first wire portion 230.

FIG. 2 illustrates that each of the gate contact portions 184, the source contact portion 186, and/or the through plug 188 has an inclined side surface such that a width of each of the gate contact portion 184, the source contact portion 186, and/or the through plug 188 becomes narrower as each of the gate contact portion 184, the source contact portion 186, and/or the through plug 188 comes closer to the second substrate 110 according to an aspect ratio when each of the gate contact portion 184, the source contact portion 186, and/or the through plug 188 is viewed in a cross-section and the bent portion is provided at the boundary portion 120p of the plurality of gate stacking structures 120a, 120b, and 120c, as non-limiting examples. It is also possible that the source contact portion 186 and/or the through plug 188 may not include the bent portion at the boundary portion 120p of the plurality of gate stacking structures 120a, 120b, and 120c. Other variations are possible.

In an embodiment, a boundary insulating pattern 132p may be provided adjacent to the boundary 120p of the plurality of gate stacking structures 120a, 120b, and 120c, such that a problem caused by falling out fr misalignment of the gate contact portion 184 that could occur at the boundary portion 120p may be prevented. Referring to FIGS. 4 to 7 together with FIG. 2, a connection structure of the gate electrode 130, the gate contact portion 184, and the boundary insulating pattern 132p will be described in more detail.

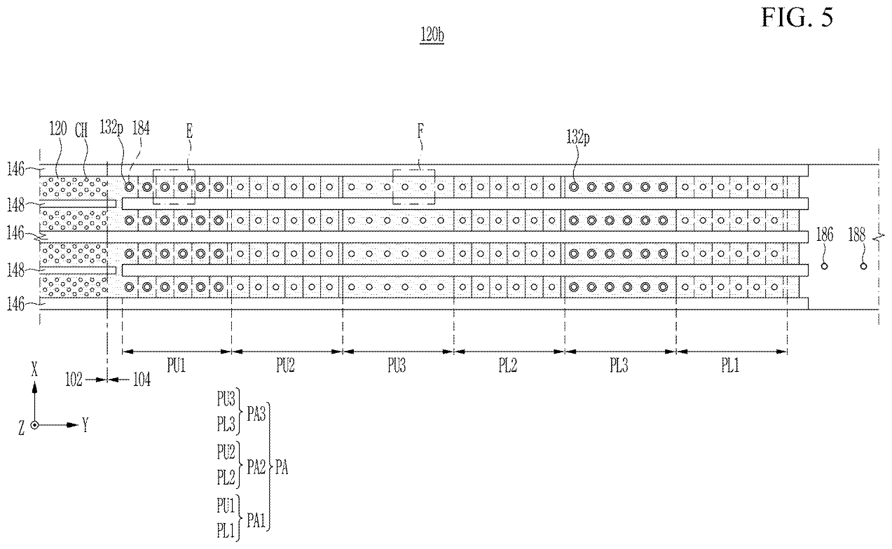

FIG. 4 is a partial cross-sectional view of the semiconductor device 10 taken along a cut line D-D′ of FIG. 1. FIG. 5 is a partial plan view illustrating an upper surface of a second gate stacking structure 120b in the semiconductor device 10 illustrated in FIG. 1. For simplicity and clarity of understanding, in FIG. 4, the second wire portion 180 may be omitted and a shape of the gate contact portion 184 is schematically illustrated. FIG. 5 mainly shows the channel structure CH, the gate contact portion 184, and the like to correspond to FIG. 1.

Referring to FIGS. 2, 4, and 5, in an embodiment, the gate electrodes 130 and the interlayer insulating layers 132m of the plurality of gate stacking structures 120a, 120b, and 120c may extend in one direction (a Y-axis direction in the drawings) to be disposed at the connection region 104. In addition, a plurality of pad areas PA to which the gate contact portion 184 and the gate electrode 130 are connected may be provided in the connection region 104. More specifically, the plurality of pad areas PA may be provided to electrically connect the plurality of gate electrodes 130 included in the plurality of gate stacking structures 120a, 120b, and 120c to the plurality of gate contact portions 184, respectively.

The pad area PA may include a pad section PS and the dummy section DS formed by the recess portion RP from which the gate electrode 130 is removed. The recess portion RP of each pad area PA may have a shape filled with the pad insulating portion 132i.

More specifically, in the pad section PS, the plurality of gate electrodes 130 may be sequentially removed by the recess portion RP. In an embodiment, in the pad section PS, lengths of the plurality of gate electrodes 130 may be sequentially increased while the lengths of the plurality of gate electrodes 130 are going downward in a direction away from the cell array region 102. For example, in the pad section PS, the plurality of gate electrodes 130 may have a stair shape that descends downward in a direction away from the cell array region 102. In this case, the plurality of gate electrodes 130 may have a stair shape in one direction or in a plurality of directions. Accordingly, in the pad section PS, a plurality of pad portions PP of a plurality of connection gate electrodes 130c may have a shape in which each of the pad portions PP is exposed upwardly.

In the dummy section DS, the plurality of gate electrodes 130 may be sequentially removed by the recess portion RP. In an embodiment, in the dummy section DS, lengths of the plurality of gate electrodes 130 may be sequentially increased while the lengths of the plurality of gate electrodes 130 may decrease om a downward direction are going toward the cell array region 102. For example, in the dummy section DS, the plurality of gate electrodes 130 may have a stair shape that descends downwardly in a direction toward the cell array region 102. The stair shape of the plurality of gate electrodes 130 in the dummy section DS may have a steeper slope than the stair shape of the plurality of gate electrodes 130 in the pad section PS, as non-limiting examples.

The above-described recess portion RP of the pad area PA may have a shape or profile for sequentially exposing the plurality of pad portions PP of the plurality of connection gate electrodes 130c in each pad area PA. The shape or profile of the recess portion RP or the gate electrode 130 in the pad section PS and the dummy section DS of each pad area PA may be the same or similar.

In an embodiment, the plurality of pad areas PA may include a first pad area PA1 connected to the gate contact portion 184 in a first gate stacking structure 120a, a second pad area PA2 connected to the gate contact portion 184 in the second gate stacking structure 120b, and a third pad area PA3 connected to the gate contact portion 184 in the third gate stacking structure 120c.

Each of the first to third pad areas PA1, PA2, and PA3 may include upper pad areas PU1, PU2, and PU3 connected to the gate contact portion 184 at upper portions of the plurality of gate stacking structures 120a, 120b, and 120c and lower pad areas PL1, PL2, and PL3 connected to the gate contact portion 184 at lower portions of the plurality of gate stacking structures 120a, 120b, and 120c. Thus, if the upper pad areas PU1, PU2, and PU3 and the lower pad areas PL1, PL2, and PL3 are separately provided, a process of forming the recess portion RP or the gate electrode 130 having the stair shape in the connection region 104 may be simplified as non-limiting examples, the number of the pad areas PA provided in each of the gate stacking structures 120a, 120b, and 120c may be one or three or more.

FIG. 4 illustrates that the first upper pad area PU1, the second upper pad area PU2, the third upper pad area PU3, the second lower pad area PL2, the third lower pad area PL3, and the first lower pad area PL1 are sequentially disposed in a direction away from the cell array region 102. However, this is only presented as an non-limiting example and the embodiment is not limited thereto.

In each pad area PA, the plurality of gate contact portions 184 may be electrically connected to each other corresponding to the pad portions PP of the plurality of connection gate electrodes 130c exposed through the recess portion RP.

In an embodiment, each gate contact portion 184 may be electrically connected to the circuit region 200 through the gate stacking structure 120 and the like. In this case, the gate contact portion 184 may be electrically connected to the connection gate electrode 130c including the pad portion PP among the plurality of gate electrodes 130 included in the gate stacking structure 120. The gate contact portion 184 may be insulated form a remaining gate electrode 130r by an insulating pattern 184i being disposed between a remaining gate electrode 130r and the gate contact portion 184.

The pad portion PP may be disposed at an end portion of the connection gate electrode 130c far from the cell array region 102, and may have a greater thickness than another portion. The gate contact portion 184 may pass through the pad portion PP of the connection gate electrode 130c, and may be connected to an inner surface of the pad portion PP. For example, the gate contact portion 184 may protrude toward an inner surface of the pad portion PP to include a connection portion 184c directly contacting the pad portion PP. A width of the insulating pattern 184i in a horizontal direction may be greater than a thickness of the remaining gate electrode 130r in a vertical or thickness direction. Accordingly, the remaining gate electrodes 130r and the gate contact portion 184 may be effectively insulated, as a non-limiting example.

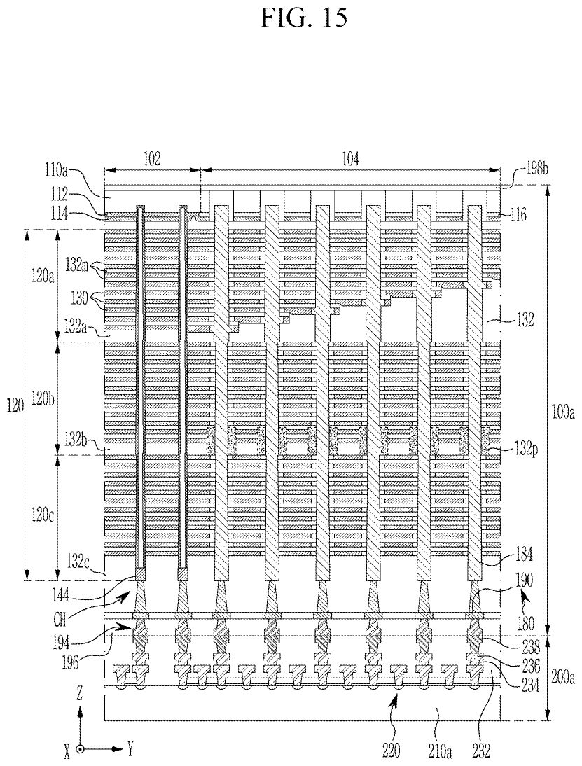

The gate contact portion 184 may pass through the gate stacking structure 120 and the like to extend to a pad portion provided at an uppermost portion of the plurality of wire layers 236 of the circuit region 200 to be connected to the pad portion. Accordingly, the gate contact portion 184 may be connected to the circuit region 200 without passing through the connection wire 190 or the like so that design freedom of the second wire portion 180 may be improved. In some implementations, a connection method between the gate contact portion 184 and the circuit region 200 may be modified in various ways. As an example, shown in FIG. 15, the gate contact portion 184 may be connected to a circuit region 200a of FIG. 15 through the connection wire 190 and a second bonding structure (or a second junction structure) 194, as will be described in detail below with reference to FIG. 15.

For example, the gate contact portion 184 may include a conductive material such as tungsten (W), copper (Cu), aluminum (Al), or the like, and may further include a diffusion prevention layer.

FIG. 4 illustrates that the plurality of pad portions PP provided within one pad area PA may include a first pad portion PP1 having a relatively short length and a second pad portion PP2 having a relatively long length. The second pad portion PP2 may be formed in consideration of a disposition of the first wire portion 230, a manufacturing process of the semiconductor device 10, or the like. The second pad portion PP2 may be periodically disposed between a plurality of first pad portions PP1, as non-limiting examples.

In an embodiment, the boundary insulating pattern 132p having a different structure from that of the insulating pattern 184i may be formed at a boundary gate electrode 130p adjacent to the boundary portion 120p. A separate insulating structure may be further provided in consideration of possible falling out or misalignment of the gate contact portion 184 at a portion adjacent to the boundary portion 120p. Accordingly, an insulating structure of the gate contact portion 184 may be effectively implemented at the boundary portion 120p.

A gate stacking structure disposed at a lower portion of one boundary portion 120p may be referred to as a lower structure, and a gate stacking structure disposed at an upper portion of the one boundary portion 120p may be referred to as an upper structure. In the first and second gate stacking structures 120a and 120b, the first gate stacking structure 120a may be a lower structure and the second gate stacking structure 120b may be an upper structure. In the second and third gate stacking structures 120b and 120c, the second gate stacking structure 120b may be a lower structure and the third gate stacking structure 120c may be an upper structure. In each pad area PA, a gate stacking structure including the connection gate electrode 130c may be referred to as a connection structure, and a gate stacking structure not including the connection gate electrode 130c may be referred to as an insulating structure.

The boundary gate electrode 130p and the boundary insulating pattern 132p may be disposed at the lower structure when the lower structure is the insulating structure and the upper structure is the insulating structure or the connection structure. That is, the boundary insulating pattern 132p may be formed adjacent to the boundary portion 120p to penetrate the boundary gate electrode 130p included in the lower structure. For reference, when the lower structure is the connection structure, the pad insulating portion 132i may be provided adjacent to the boundary portion 120p, and the boundary insulating pattern 132p may not be provided.

In an embodiment, the boundary insulating pattern 132p may be formed at the second gate stacking structure 120b in the first upper pad area PU1 and the third lower pad area PL3. In the first upper pad area PU1, the second gate stacking structure 120b is the lower structure that includes the insulating structure. The third gate stacking structure 120c is the upper structure that includes the insulating structure. In the third lower pad area PL3, the second gate stacking structure 120b is the lower structure that includes the insulating structure, and the third gate stacking structure 120c is the upper structure that includes the connection structure.

In the first upper pad area PU1, the boundary gate electrode 130p of the second gate stacking structure 120b is disposed between the cell array region 102 and the second upper pad area PU2, such that an electrical connection path is maintained. The boundary insulating pattern 132p according to an embodiment may not obstruct the electrical connection path. Accordingly, when the boundary insulating pattern 132p is provided in the second gate stacking structure 120b in the first upper pad area PU1, a problem that could be due to falling out or misalignment of the gate contact portion 184 may be prevented while maintaining the electrical connection path.

The boundary gate electrode 130p of the second gate stacking structure 120b in the third lower pad area PL3 is not a portion where the electrical connection path has to be maintained. However, an upper portion of the gate contact portion 184 penetrating the third gate stacking structure 120c in the third lower pad area PL3 may be formed within the pad insulating portion 132i such that the upper portion of the gate contact portion 184 has a relatively larger width than another portion of the gate contact portion 184. If the boundary insulating pattern 132p is formed at the boundary gate electrode 130p of the second gate stacking structure 120b disposed below the upper portion of the gate contact portion 184, a problem that could be caused by a falling out or misalignment of the gate contact portion 184 may be more effectively prevented.

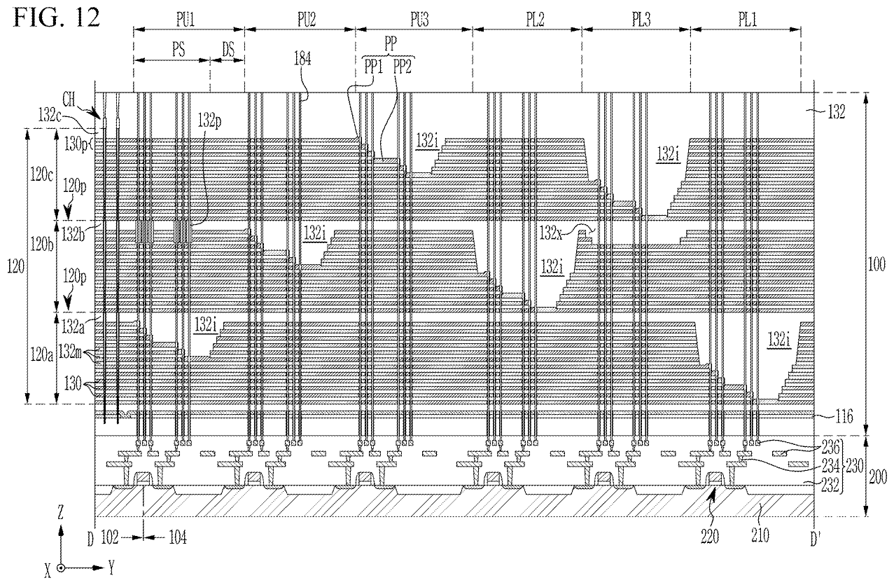

For example, FIGS. 4 and 5 illustrate that the boundary insulating pattern 132p may be formed at the second gate stacking structure 120b in the first upper pad area PU1 and the third lower pad area PL3, as a non-limiting example. Accordingly, at least one boundary insulating pattern 132p may be formed at a lower structure (e.g., the first or second gate stacking structure 120a or 120b) including an insulating structure in one or a plurality of pad areas PA. An example of a different formation position of the boundary insulating pattern 132p will be described in detail below with reference to FIGS. 12 to 14.

In addition, FIGS. 4 and 5 illustrate that a plurality of boundary insulating patterns 132p may be formed to correspond to the plurality of gate contact portions 184 provided in one pad area PA, respectively. Accordingly, the boundary insulating pattern 132p may be provided in the plurality of gate contact portions 184 to effectively prevent a problem that could be caused by a falling out or misalignment of the plurality of gate contact portions 184, as a non-limiting example. Accordingly, the boundary insulating pattern 132p may be formed to correspond to at least one of the plurality of gate contact portions 184 disposed within one pad area PA.

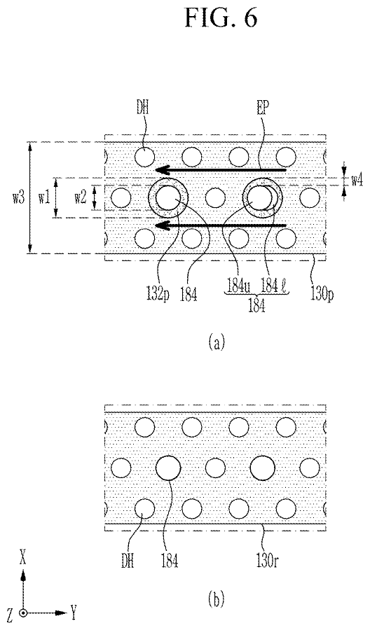

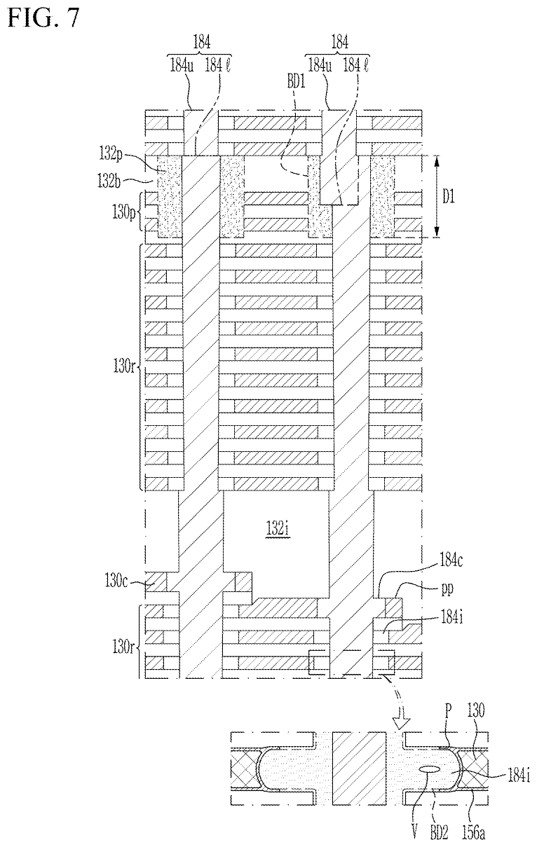

A shape of the boundary insulating pattern 132p will be described in more detail with reference to FIGS. 6 and 7. FIG. 6 (a) and FIG. 6 (b) are enlarged views of portions E and F of FIG. 5, and FIG. 7 is an enlarged view of a portion G of FIG. 2.

Referring to FIGS. 6 and 7, in an embodiment, the boundary insulating pattern 132p may be formed to surround the gate contact portion 184 in the boundary gate electrode 130p. In this case, when the boundary insulating pattern 132p is viewed in a plan view, the boundary insulating pattern 132p may be seen as a closed shape that does not cut the boundary gate electrode 130p. Accordingly, the boundary insulating pattern 132p may be partially formed while maintaining an electrical connection path EP of the boundary gate electrode 130p. Therefore, even if the boundary insulating pattern 132p were to be disposed between the cell array region 102 and the pad area PA, the connection between the cell array region 102 and the pad area PA is secured.

More specifically, an entire width W1 of the boundary insulating pattern 132p in a width direction (an X-axis direction in the drawings) of the boundary gate electrode 130p may be greater than a width W2 of the gate contact portion 184 and may be less than a width W3 of the boundary gate electrode 130p. The term “entire width W1 of the boundary insulating pattern 132p” may refer to a largest value among widths of the boundary insulating pattern 132p with respect to an outer edge in a width direction of the boundary gate electrode 130p. Further, the term “width W3 of the boundary gate electrode 130p” may be defined as a maximum distance between two adjacent separation structures 146 in a second direction (an X-axis direction in the drawings) or between both edges of the boundary gate electrode 130p in the second direction. In the width direction of the boundary gate electrode 130p, the boundary insulating pattern 132p may be disposed at an inner or central portion of the boundary gate electrode 130p so that the electrical connection path EP is provided at both sides of the boundary insulating pattern 132p.

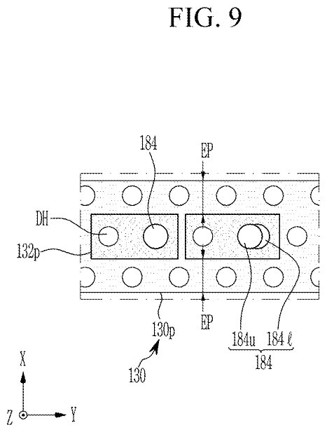

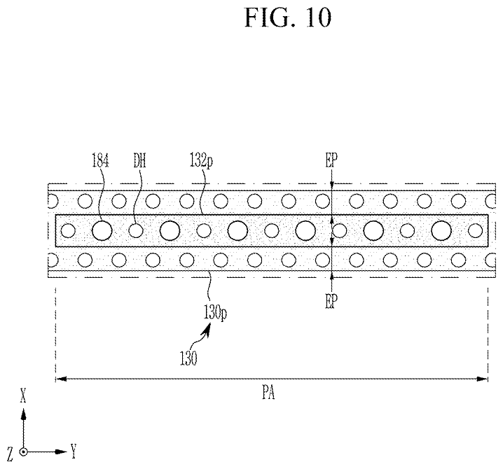

The drawings illustrate that the boundary insulating pattern 132p has a circular shape surrounding one gate contact portion 184 when the boundary insulating pattern 132p is viewed in a plan view. In some implementations, the boundary insulating pattern 132p may have other shapes (for example, an elliptical shape, a polygonal shape, a line shape, or the like) capable of maintaining the electrical connection path EP. The boundary insulating pattern 132p may entirely surround the gate contact portion 184 or may partially surround the gate contact portion 184. In addition, a shape, a disposition, or the like of the boundary insulating pattern 132p may be variously modified. Another embodiment of the boundary insulating pattern 132p will be described in detail below with reference to FIGS. 9 and 10.

In an embodiment, a plurality of boundary gate electrodes 130p having the boundary insulating patterns 132p may be provided. Accordingly, a problem that could be caused by a falling out or misalignment of the gate contact portion 184 may be effectively prevented. For example, up to 20 boundary gate electrodes 130p including the boundary insulating patterns 132p may be provided. In some implementations, and referring to FIG. 4, an entire depth D1 of the boundary insulating pattern 132p may be 1 nm to 1000 nm. Within this range, a manufacturing process may be simplified while sufficiently implementing an effect of the boundary insulating pattern 132p. In some implementations, the entire depth D1 of the boundary insulating pattern 132p may be equal to or less than an entire depth D2 of the first or second upper pad areas PU1 and PU2 disposed adjacent to the boundary portion 120p. The boundary insulating pattern 132p may be formed without interfering with an electrical connection path in the first or second lower pad area PL1 or PL2. Here, the term “entire depth D1 of the boundary insulating pattern 132p” may refer to the largest value among depths of the boundary insulating pattern 132p or a depth of the boundary insulating pattern 132p at a portion where the gate contact portion 184 is not provided. The term “entire depth D2 of the first or second upper pad area PU1 or PU2” may refer to the largest depth.

For example, the entire width W1 of the boundary insulating pattern 132p may be 100 nm to 1000 nm, and a peripheral width W4 of the boundary insulating pattern 132p may be 1 nm to 300 nm. Here, the term “peripheral width W4 of the boundary insulating pattern 132p” may refer to the smallest value among distances between an outer edge of the gate contact portion 184 and an outer edge of the boundary insulating pattern 132p. Accordingly, a problem that could be caused by a falling out or misalignment of the gate contact portion 184 may be effectively prevented within this range, and a size of the boundary insulating pattern 132p may be prevented from being too large.

For example, in some implementations, in the boundary insulating pattern 132p, the entire depth D1 may be greater than the peripheral width W4 from an outer edge of the gate contact portion 184. This takes into account that a problem could occur in a depth direction due to misalignment of the gate contact portion 184. However, the embodiment is not limited thereto. In some implementations, the entire depth D1 of the boundary insulating pattern 132p may be equal to or less than the peripheral width W4 from the outer edge of the gate contact portion 184, as a non-limiting example.

The entire width W1 or the peripheral width W4 of the boundary insulating pattern 132p, the number of boundary gate electrodes 130p, or the entire depth D1 of the boundary insulating pattern 132p may be variously modified to physically and electrically separate the boundary gate electrode 130p and the gate contact portion 184. For example, the entire width W1 or the peripheral width W4 of the boundary insulating pattern 132p, the number of boundary gate electrodes 130p, or the entire depth D1 of the boundary insulating pattern 132p may be adjusted in consideration of a misalignment size of the gate contact portion 184, a depth at which an upper portion 184u of the gate contact portion 184 extends to a lower structure, or the like.

The entire width W1 or the peripheral width W4 of the boundary insulating pattern 132p, the entire depth D1 of the boundary insulating pattern 132p, the width W2 of the gate contact portion 184, the width W3 of the boundary gate electrode 130p, or the like may be measured or determined from a micrograph. For example, the width or the depth may be measured or determined from a transmission electron microscope (TEM) photograph, a scanning electron microscope (SEM) photograph, or the like, and photographing a cross-section or a plane.

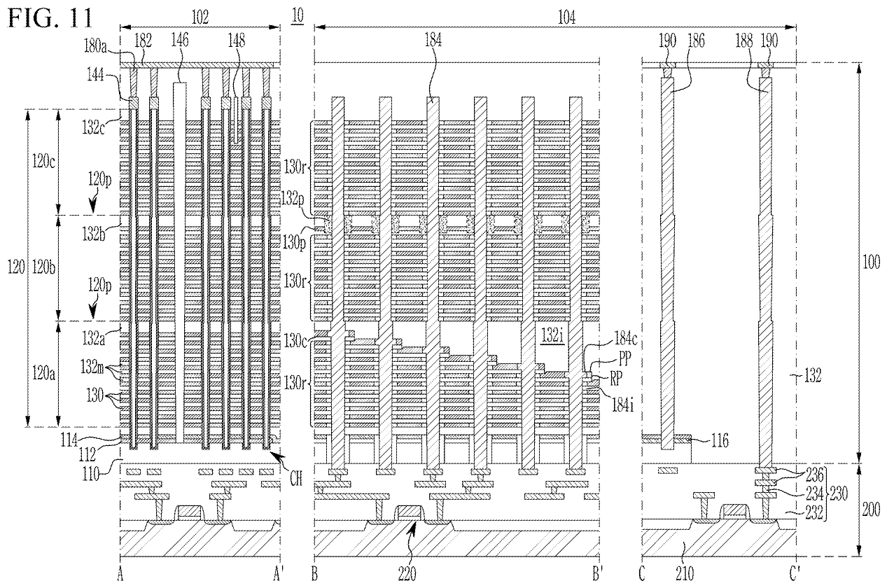

According to an embodiment, more than 20 boundary gate electrodes 130p may be provided. In some implementations, the entire depth D1 of the boundary insulating pattern 132p may be greater than the entire depth D2 of the first or second upper pad area PU1 or PU2. In some implementations, only one boundary gate electrode 130p may be provided. The one boundary gate electrode 130p will be described in detail below with reference to FIG. 11.

If the gate contact portion 184 is disposed without falling out or being misaligned as shown in a left side of FIG. 6 (a) or FIG. 7, the upper portion 184u of the gate contact portion 184 disposed at an upper structure may be stably disposed on a lower portion 184l of the gate contact portion 184 disposed at a lower structure when the gate contact portion 184 is viewed in a cross-section. In this case, an issue due to falling out of the gate contact portion 184 may not arise.

In some implementations, if the boundary insulating pattern 132p is not provided, then if the upper portion 184u of the gate contact portion 184 is not completely disposed on the lower portion 184l as shown in a right side of FIG. 6 (b) or FIG. 7, the upper portion 184u of the gate contact portion 184 might reach the boundary gate electrode 130p adjacent to the boundary portion 120p in the lower structure, resulting in damage to the boundary gate electrode 130p. If the boundary insulating pattern 132p having the entire width W1 with sufficient size and the sufficient entire depth D1 with sufficient size is formed as in the embodiment, the boundary insulating pattern 132p may be formed while entirely surrounding a bonding portion (or a junction portion) between the upper portion 184u and the lower portion 184l of the gate contact portion 184 at the boundary portion 120p. In particular, the boundary insulating pattern 132p may entirely cover a lower portion of the upper portion 184u of the gate contact portion 184 that protrudes to a lower structure. Accordingly, it may be possible to fundamentally prevent a problem from occurring in which the gate contact portion 184 damages the boundary gate electrode 130p due to falling out or misalignment of the gate contact portion 184.

In an embodiment, the boundary insulating pattern 132p may be different from the insulating pattern 184i, may be provided separately from the insulating pattern 184i, and may have a different structure from that of the insulating pattern 184i. This could be because the boundary insulating pattern 132p and the insulating pattern 184i could be formed by different methods in different processes. Here, having different structures may include having a difference in at least one of a shape, a material, a stacking structure, presence or absence of a void, a shape of a void, and a size by being formed by different processes and/or different methods or being perceived differently due to a difference in at least one of various characteristics such as a shape, a material, a stacking structure, presence or absence of a void, a shape of a void, a size, and the like.

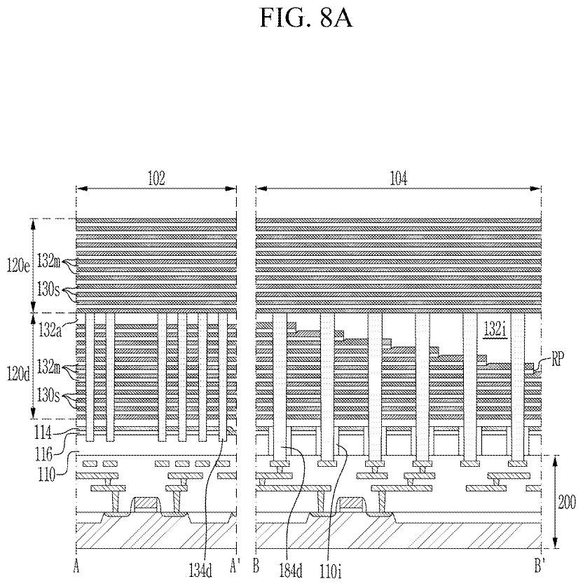

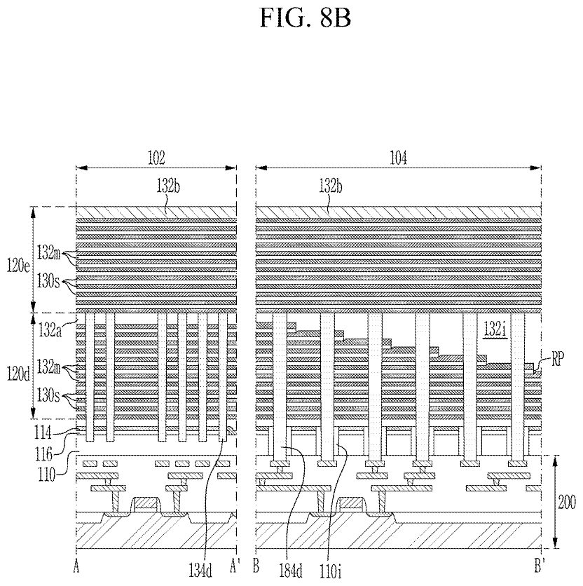

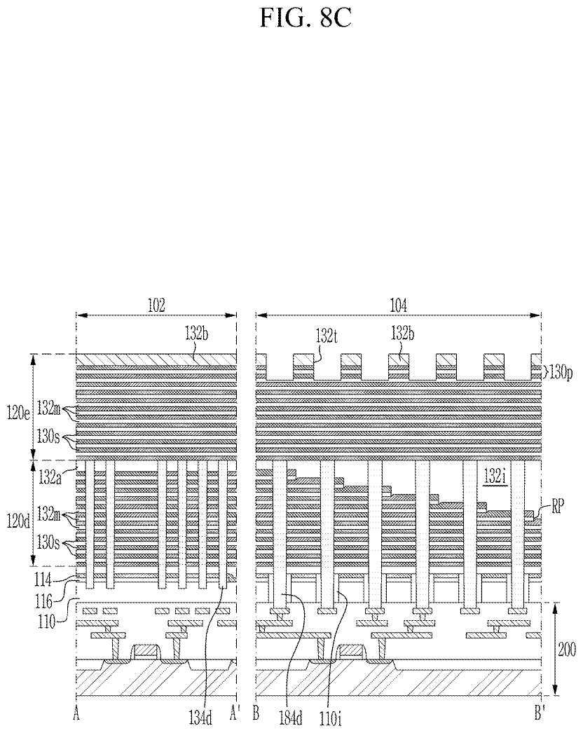

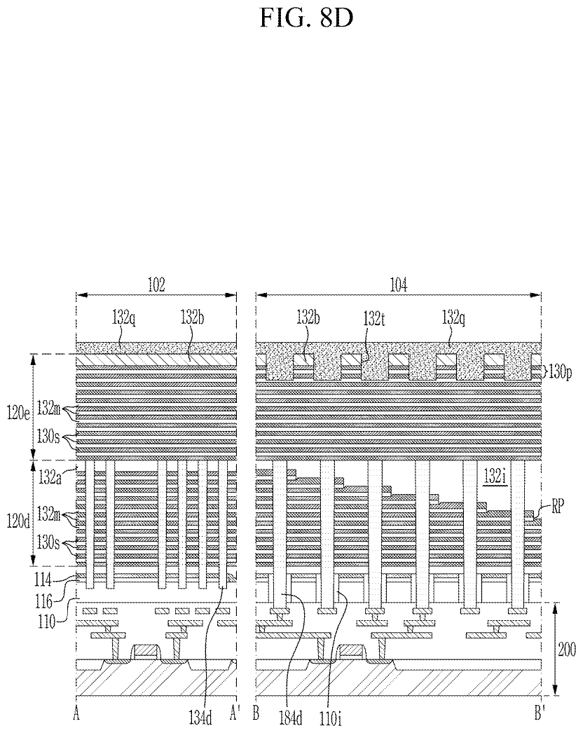

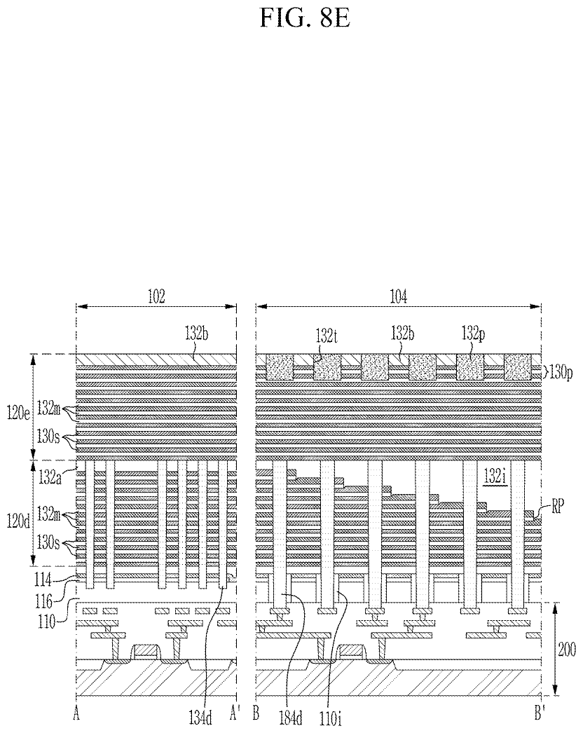

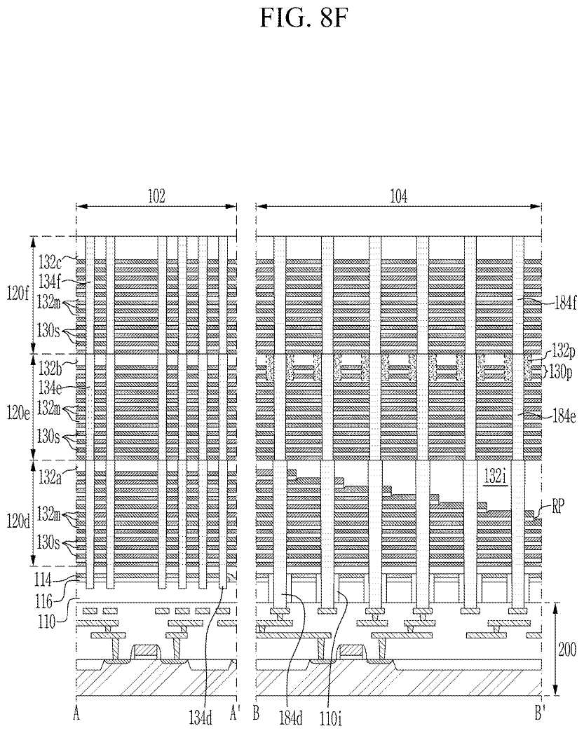

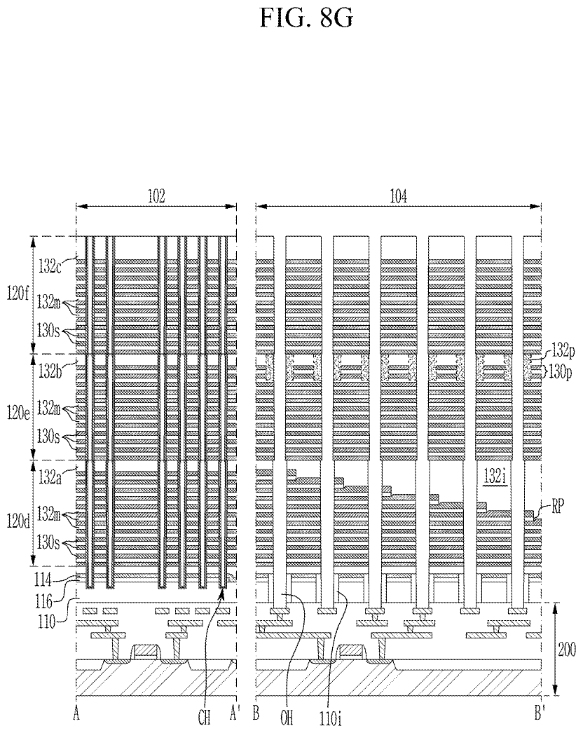

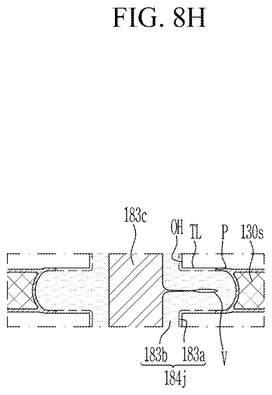

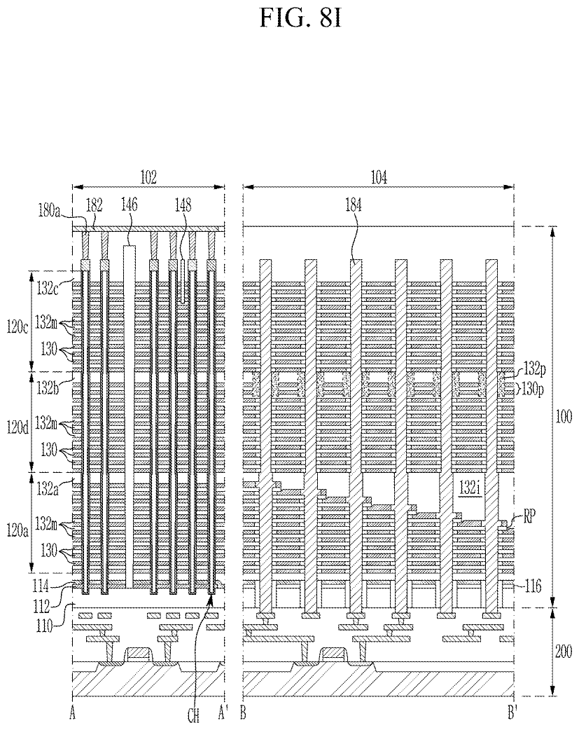

More specifically, a tunnel portion TL as shown in FIG. 8H may be formed by etching in a horizontal direction (a direction parallel to an XY-plane in the drawings) through a wire penetrating portion OH of FIG. 8G for forming the gate contact portion 184 A portion of a preliminary insulating layer 184j of FIG. 8H formed within the tunnel portion TL may remain to form the insulating pattern 184i. However, after an intermediate insulating layer (e.g., the first or second upper insulating layer 132a or 132b) adjacent to the boundary portion 120p is formed, and then the formed intermediate insulating layer is etched in a vertical direction (a Z-axis direction in the drawings) so that a trench 132t of FIG. 8C is formed, an insulating material may be filled in the trench 132t to form the boundary insulating pattern 132p. Manufacturing processes of the insulating pattern 184i and the boundary insulating pattern 132p will be described in more detail below with reference to FIGS. 8A to 8I.

The insulating pattern 184i may have a horizontal etching structure etched in a horizontal direction and a horizontal filling structure filled in a horizontal direction. In some implementations, the boundary insulating pattern 132p may have a vertical etching structure that is etched in a vertical direction and a vertical filling structure that is filled in a vertical direction.

For example, since the tunnel portion TL is formed by etching in the horizontal direction through the wire penetrating portion OH when the insulating pattern 184i is formed, a side surface of the insulating pattern 184i may have a relatively small slope or may include a convex shape or a rounded portion. For example, as shown in an enlarged view of FIG. 7, the side surface of the insulating pattern 184i adjacent to the gate electrode 130 may have a convex shape toward the gate electrode 130. For example, on a cross-section, the side surface of the insulating pattern 184i may have an overall convex shape toward the gate electrode 130 such that a central portion has a shape in which the central portion protrudes the most toward the gate electrode 130. However, since the trench 132t is formed by etching in a vertical direction from an upper portion to a lower portion after forming the intermediate insulating layer in a process of forming the boundary insulating pattern 132p, an entire side surface of the boundary insulating pattern 132p may be configured as an inclined surface having a greater slope than that of the insulating pattern 184i and gradually decreasing in width toward the second substrate 110. In some implementations, the entire side surface of the boundary insulating pattern 132p may be configured as a vertical surface perpendicular to the second substrate 110.

In some implementations, a void V extending in a horizontal direction may be provided in the insulating pattern 184 due to the preliminary insulating layer 184j being filled in the tunnel portion TL in the horizontal direction when the insulating pattern 184i is formed. In some implementations, the boundary insulating pattern 132p may not have a void. A void that extends in a vertical direction may be provided when an insulating material is filled in a manufacturing process of forming the boundary insulating pattern 132p., The void may disappear when the void is formed at a central portion of the boundary insulating pattern 132p to form the wire penetrating portion OH. In some implementations, even when a void remains in the boundary insulating pattern 132p, the void may have a shape that extends in a vertical direction.

In some implementations, the insulating pattern 184i may be formed by forming a plurality of insulating layers (e.g., first and second preliminary insulating layers 183a and 183b of FIG. 8H). Accordingly, a boundary BD2 may be provided between a plurality of insulating layers having different materials or compositions. in some implementations, a step P may be provided at an upper surface and/or a lower surface of the insulating pattern 184i. A portion of the first blocking layer 156a and/or the gate electrode 130 may be disposed at the upper surface and/or the lower surface of the insulating pattern 184i. In some implementations, the boundary insulating pattern 132p may be formed by entirely filling one insulating material after forming the trench 132t. Accordingly, a side surface of the boundary insulating pattern 132p may be a continuous inclined surface or a vertical surface with a constant slope as a whole. The boundary insulating pattern 132p may include an insulating material of a single composition. For example, the boundary insulating pattern 132p may include a silicon oxide.

For example, after the first preliminary insulating layer 183a including a silicon oxynitride and the second preliminary insulating layer 183b including a silicon oxide are formed within the tunnel portion TL, an oxidation treatment process may be performed on the first preliminary insulating layer 183a. A portion of the first preliminary insulating layers 183a and a portion of the second preliminary insulating layer 183b may remain to form the insulating pattern 184i. In the oxidation treatment process, a portion of the first preliminary insulating layer 183a adjacent to the wire penetrating portion OH may be changed into a silicon oxide layer, and a portion of the first preliminary insulating layer 183a far from the wire penetrating portion OH may remain as a silicon oxynitride layer without being oxidized. Then, since the remaining unoxidized silicon oxynitride layer is removed when a sacrificial insulating layer 130s is removed in a process of replacing the sacrificial insulating layer 130s of FIG. 8A with the gate electrode 130, the first blocking layer 156a and/or the gate electrode 130 may be formed at the removed portion. Accordingly, at an upper surface and/or a lower surface of the tunnel portion TL, a portion of the first preliminary insulating layer 183a changed to the silicon oxide layer adjacent to the wire penetrating portion OH may remain as a portion of the insulating pattern 184i, and a portion of the first preliminary insulating layer 183a remaining as the unoxidized silicon oxynitride layer far from the wire penetrating portion OH may be replaced with the first blocking layer 156a and/or the gate electrode 130. Accordingly, the step P may be provided at the upper surface and/or the lower surface of the insulating pattern 184i, or the portion of the first blocking layer 156a and/or the gate electrode 130 may be disposed.

In some implementations, the boundary insulating pattern 132p may be distinguished from the insulating pattern 184i or the cell insulating layer 132 by having a material or a composition different from that of the insulating pattern 184i or the cell insulating layer 132. In some implementations, even when the boundary insulating pattern 132p has the same material or composition as the insulating pattern 184i or the cell insulating layer 132, a boundary BD1 of the boundary insulating pattern 132p may be confirmed in a transmission micrograph (TEM) or the like. From the transmission micrograph (TEM) or the like, it may be confirmed that the boundary insulating pattern 132p is provided. When the boundary BD1 of the boundary insulating pattern 132p is confirmed, it may be seen that the boundary insulating pattern 132p extends downward from an upper surface of the intermediate insulating layer (e.g., the first or second upper insulating layer 132a or 132b) to pass through the boundary gate electrode 130p.

According to an embodiment, the boundary insulating pattern 132p may be partially formed at the boundary gate electrode 130p disposed at a lower portion of the boundary portion 120p in which a bonding portion (or a junction portion) of the gate contact portion 184 is disposed in the connection region 104. Accordingly, the upper portion 184u of the gate contact portion 184 may be disposed within the boundary insulating pattern 132p provided in a lower structure even if the gate contact portion 184 were to fall out at the boundary portion 120p. Accordingly, the gate contact portion 184 and the boundary insulating pattern 132p may be separated while having a sufficient physical and electrical separation distance. Thus, it may be possible to fundamentally prevent the gate contact portion 184 from damaging the boundary gate electrode 130p at the boundary portion 120p.

In addition, since the boundary insulating pattern 132p is only partially formed adjacent to the boundary portion 120p, the electrical connection path EP may be maintained as it is. Accordingly, the boundary insulating pattern 132p may be formed at any of various positions regardless of a disposition or the like of the plurality of pad areas PA. Thus, the boundary insulating pattern 132p may be applied to all pad areas PA as desired. However, unlike the embodiment, if the gate electrode were to be entirely removed from the pad area PA, there could be a pad area PA that is not be applied to the boundary insulating pattern 132p because the electrical connection path EP may not be provided.

An example of a manufacturing method for manufacturing the semiconductor device 10 having the above structure will be described in detail with reference to FIGS. 8A to 8I together with FIGS. 1 to 7. A detailed description of a portion that has already been described will not be repeated, and a portion that has not been described will be described in detail.

FIGS. 8A to 8I are partial cross-sectional views illustrating the method for manufacturing the semiconductor device according to an embodiment. FIGS. 8A to 8G and 8I show partial cross-sectional views of the semiconductor device 10 cut along a line A-A′ and a line B-B′ of FIG. 1, and FIG. 8H shows a portion corresponding to the enlarged view shown in FIG. 7. Hereinafter, the method for manufacturing the semiconductor device 10 will mainly describe the gate stacking structure 120, the channel structure CH, and the gate contact portion 184 formed in the cell region 100.

As shown in FIG. 8A, the second substrate 110, the horizontal insulating layer 116 of FIG. 1, the second horizontal conductive layer 114, a first stacking structure 120d, and a second stacking structure 120e may be formed on the circuit region 200.

Here, the first stacking structure 120d may include the sacrificial insulating layers 130s and the interlayer insulating layers 132m alternately stacked, the recess portion RP formed corresponding to the first pad area PA1 of FIG. 1, a first upper insulating layer 132a entirely covering the sacrificial insulating layer 130s, the interlayer insulating layer 132m, the recess portion RP, a first channel sacrificial layer 134d and a first wire sacrificial layer 184d penetrating the first stacking structure 120d. The second stacking structure 120e may include the sacrificial insulating layers 130s and the interlayer insulating layers 132m alternately stacked on the first stacking structure 120d, and the recess portion RP formed corresponding to the second pad area PA2 of FIG. 1.

First, the horizontal insulating layer 116 and the second horizontal conductive layer 114 may be formed on the second substrate 110, and the interlayer insulating layers 132m and the sacrificial insulating layer 130s may be alternately stacked above the second horizontal conductive layer 114. In addition, the first upper insulating layer 132a may be formed. Here, the sacrificial insulating layer 130s may be a layer that is replaced with the gate electrode 130 of FIG. 1 through a subsequent process, and at least a portion of the horizontal insulating layer 116 may be a layer replaced with the conductive layer 112 of FIG. 1 through a subsequent process. For example, the sacrificial insulating layer 130s may be formed to correspond to a portion where the gate electrode 130 is to be formed, and the horizontal insulating layer 116 may be formed to include a portion where the first horizontal conductive layer 112 is to be formed.

The horizontal insulating layer 116 and/or the sacrificial insulating layer 130s may be formed of a different material from that of the interlayer insulating layer 132m. For example, the interlayer insulating layer 132m may include a silicon oxide, a silicon nitride, a silicon oxynitride, a low dielectric constant material, or the like, and the sacrificial insulating layer 130s may include a silicon, a silicon oxide, a silicon carbide, a silicon nitride, or the like, and may be formed of a different material from that of the interlayer insulating layer 132m.

Subsequently, the recess portion RP may be formed to correspond to the first pad area PA1. For example, the recess portion RP provided in the first upper pad area PU1 and the first lower pad area PL1 as shown in FIG. 4 may be formed at a plurality of interlayer insulating layers 132m and the plurality of sacrificial insulating layers 130s. The recess portion RP may be formed by a sequential etching process using a mask layer. For example, the recess portion RP may be formed by performing a stepwise etching process on the sacrificial insulating layer 130s and the interlayer insulating layer 132m while sequentially increasing an exposed region using the mask layer.

Next, a thickness of the sacrificial insulating layer 130s in the pad portion PP of the gate electrode 130 may be increased more than a thickness of the sacrificial insulating layer 130s in another portion. For example, after an additional sacrificial insulating layer is formed, a thickness of the sacrificial insulating layer 130s of the pad portion PP may be increased by patterning so that the additional sacrificial insulating layer remains only on the pad portion PP.

Subsequently, the first upper insulating layer 132a may be formed to entirely cover the sacrificial insulating layer 130s and the interlayer insulating layer 132m. The pad insulating portion 132i filling the recess portion RP may be formed separately from the first upper insulating layer 132a before the first upper insulating layer 132a is formed, or may be formed as a portion of the first upper insulation layer 132a.

Next, the first channel sacrificial layer 134d penetrating the first stacking structure 120d may be formed in the cell array region 102. The first wire sacrificial layer 184d penetrating the first stacking structure 120d may be formed in the connection region 104. The first channel sacrificial layer 134d may be formed to correspond to the first channel structure CH1 of FIG. 3. The first wire sacrificial layer 184d may be formed to correspond to a portion of the gate contact portion 184 formed at the first stacking structure 120a of FIG. 2. The first channel sacrificial layer 134d and the first wire sacrificial layer 184d may be formed by depositing a sacrificial material after a penetrating portion (or a through portion) penetrating the first stacking structure 120d is formed. The first channel sacrificial layer 134d or the first wire sacrificial layer 184d may include, for example, a polycrystalline silicon, tungsten, or the like.

Subsequently, the second stacking structure 120e including the sacrificial insulating layers 130s and the interlayer insulating layers 132m alternately stacked on the first stacked structure 120d and the recess portion RP formed corresponding to the second pad area PA2 of FIG. 1 may be formed.

Here, the second stacking structure 120e may include the sacrificial insulating layers 130s and the interlayer insulating layers 132m alternately stacked, the recess portion RP formed corresponding to the second pad area PA2 of FIG. 1, and the pad insulating portion 132i filling the recess portion RP. In this case, the recess portion RP may be formed in a shape provided in the second upper pad area PU2 and the second lower pad area PL2 shown in FIG. 4. Since a description related to the first stacking structure 120d may be applied to a manufacturing process of the sacrificial insulating layer 130s, the interlayer insulating layer 132m, the recess portion RP, and the pad insulating portion 132i of the second stack structure 120e, a detailed description of the manufacturing process will not be repeated.

Subsequently, as shown in FIG. 8B, the second upper insulating layer 132b may be formed to entirely cover the second stacking structure 120e. The second upper insulating layer 132b may have a greater thickness than the interlayer insulating layer 132m, and may include a silicon oxide or the like.

Subsequently, as shown in FIG. 8C, the trench 132t is formed to form the boundary insulating pattern 132p of FIG. 8E by partially etching the second upper insulating layer 132b. The trench 132t may have a vertical etching structure formed by etching the second upper insulating layer 132b and the boundary gate electrode 130p in a vertical direction. The trench 132t may be formed by etching the second upper insulating layer 132b and the boundary gate electrode 130p in the vertical direction after the second upper insulating layer 132b is formed. Accordingly, an entire side surface of the trench 132t may be configured as an inclined surface gradually decreasing in width toward the second substrate 110. Alternatively, the entire side surface of the trench 132t may be configured as a vertical surface perpendicular to the second substrate 110.

Subsequently, as illustrated in FIGS. 8D and 8E, the boundary insulating pattern 132p may be formed by filling the trench 132t with an insulating material. For example, after an insulating layer 132q is formed entirely on the second stacking structure 120e while filling the trench 132t as shown in FIG. 8D, the insulating layer 132q may be planarized to be disposed within the trench 132t, as shown in FIG. 8E. For example, the insulating layer 132q may be formed by depositing an oxide. Planarization of the insulating layer 132q may be performed by chemical mechanical polishing (CMP).

Thus, the boundary insulating pattern 132p may have a vertical filling structure filled in a vertical direction from a lower portion of the trench 132t toward an upper portion of the trench 132t. In this case, since one insulating material is entirely filled in the trench 132t, after the trench 132t is formed, the trench 132t may be filled with an insulating material having a single composition. For example, the boundary insulating pattern 132p may include a silicon oxide.

Subsequently, as shown in FIG. 8F, a second channel sacrificial layer 134e and a second wire sacrificial layer 184e penetrating the second stacking structure 120e may be formed, and a third stacking structure 120f may be formed on the second stacking structure 120e. Since a description related to the first stacking structure 120d may be applied to manufacturing processes of the second channel sacrificial layer 134e and the second wire sacrificial layer 184e, a detailed description of the manufacturing processes will not be repeated.

The third stacking structure 120f may include the sacrificial insulating layers 130s and the interlayer insulating layers 132m alternately stacked, the recess portion RP formed corresponding to the third pad area PA3 of FIG. 1, the third upper insulating layer 132c entirely covering the sacrificial insulating layer 130s, the interlayer insulating layer 132m, and the recess portion RP, and a third channel sacrificial layer 134f and a third wire sacrificial layer 184f penetrating the third stacking structure 120f. In this case, the recess portion RP may be formed in a shape provided in the third upper pad area PU3 and the third lower pad area PL3 shown in FIG. 4. Since a description related to the first stacking structure 120d may be applied to manufacturing processes of the sacrificial insulating layer 130s, the interlayer insulating layer 132m, the recess portion RP, the third upper insulating layer 132c, the third channel sacrificial layer 134f, and the third wire sacrificial layer 184f of the third stacking structure 120f, a detailed description of the manufacturing processes will not be repeated.

Subsequently, as shown in FIG. 8G, the channel structure CH and the wire penetrating portion OH may be formed. The upper separation region 148 may be further formed at a portion of the third stacking structure 120f. The upper separation region 148 may be formed by forming an upper separation opening by an etching process using a mask layer and depositing an insulating material within the upper separation opening.

Subsequently, the channel structures CH may be formed within penetrating portions (or through portions) formed by removing the first to third channel sacrificial layers 134d, 134e, and 134f of FIG. 8F. For example, the gate dielectric layer 150 of FIG. 3, the channel layer 140 of FIG. 3, and the core insulating layer 142 of FIG. 3 may be sequentially formed to fill the penetrating portion the channel pad 144 of FIG. 3 may be formed on the channel layer 140 to form the channel structure CH. In this case, the first blocking layer 156a of FIG. 3 of the gate dielectric layer 150 may not be formed at this time, but may be formed in another process later.

In addition, the first to third wiring sacrificial layers 184d, 184e, and 184f of FIG. 8F may be removed to form the wire penetrating portion OH. A portion of the cell insulating layer 132 covering the channel structure CH may be further formed before the wire penetrating portion OH is formed. The wire penetrating portion OH may be extended to the circuit region 200 by penetrating the first to third layer structures 120d, 120e, 120f and penetrating the substrate insulating portion 110i of the second substrate 110. The wire penetrating portion OH may be formed to expose a pad portion of the circuit region 200.

Subsequently, as shown in FIG. 8H, the tunnel portion TL may be formed and the preliminary insulating layer 184j and a vertical sacrificial layer 183c may be formed.

More specifically, a portion of the sacrificial insulating layer 130s exposed through the wire penetrating portion OH may be removed in a horizontal direction to form the tunnel portion TL. When an etching material is introduced through the wire penetrating portion OH, the sacrificial insulating layer 130s adjacent to the wire penetrating portion OH may be etched in a horizontal direction to form the tunnel portion TL. In this case, etching may also be performed in upper and lower directions of the sacrificial insulating layer 130s, such that the tunnel portion TL may be formed to have a thickness slightly thicker than that of the sacrificial insulating layer 130s. Since the tunnel portion TL is formed by etching in the horizontal direction through the wire penetrating portion OH, a side surface of the tunnel portion TL may have a relatively small slope, a convex shape, or a rounded portion.

The tunnel portion TL may be formed to have a relatively short length at the pad portion pp of the connection gate electrode 130c, and the tunnel portion TL may be formed to have a relatively long length at the remaining gate electrode 130r. For this purpose, after the tunnel portion TL is formed, an additional sacrificial insulating layer may be formed within the wire penetrating portion OH and the tunnel portion TL.

Subsequently, the preliminary insulating layer 184j and the vertical sacrificial layer 183c may be filled in the tunnel portion TL and the wire penetrating portion OH.

The preliminary insulating layer 184j may be a layer that constitutes the insulating pattern 184i by allowing a portion of the preliminary insulating layer 184j to remain. For example, the insulating pattern 184i may include the first preliminary insulating layer 183a and the second preliminary insulating layer 183b. The first preliminary insulating layer 183a may include a silicon oxynitride, and the second preliminary insulating layer 183b may include a silicon oxide. Thereafter, an oxidation treatment process may be performed on the first preliminary insulating layer 183a formed of a silicon oxynitride layer. In the first preliminary insulating layer 183a. A portion that is adjacent to the wire penetrating portion OH may be oxidized and transformed into a silicon oxide layer. A portion far from the wire penetrating portion OH may remain as a silicon oxynitride layer without being oxidized. In FIG. 8H, a portion that is indicated by a dotted line may refer to a portion that is changed to the silicon oxide layer in the first preliminary insulating layer 183a. A portion that is indicated by a solid line may refer to a portion that remains as the silicon oxynitride layer in the first preliminary insulating layer 183a.

The preliminary insulating layer 184j may not completely fill the tunnel portion TL that is formed corresponding to the pad portion PP of the connection gate electrode 130c of FIG. 2 having a relatively large thickness, The preliminary insulating layer 184j may be formed to fill the tunnel portion TL that is formed corresponding to the remaining gate electrode 130r of FIG. 2, due to a relative thickness difference. The preliminary insulating layer 184j may be formed so that a void V remains in at least a portion of the remaining gate electrode 130r. The vertical sacrificial layer 183c may be formed to fill a remaining space within the wire penetrating portion OH. The vertical sacrificial layer 183c may include a different material from that of the preliminary insulating layer 184j. For example, the vertical sacrificial layer 183c may include a polycrystalline silicon, tungsten, or the like.

Subsequently, as shown in FIG. 8I, the gate contact portion 184 may be formed by replacing the sacrificial insulating layer 130s of FIGS. 8G and 8H with the gate electrode 130.

First, an opening may be formed at a region corresponding to the separation structure 146 of FIG. 2 to pass through the first to third gate stacking structures 120a, 120b, and 120c. The sacrificial insulating layer 130s may be selectively removed by an etching process (e.g., a wet etching process) through the opening. In addition, the gate electrode 130 may be formed by filling a conductive material constituting the gate electrode 130 in a portion where the sacrificial insulating layer 130s is removed. Accordingly, regions where the sacrificial insulating layers 130s are disposed may be replaced with the gate electrodes 130. In this case, a process of forming the first blocking layer 156a may be further performed before a process of filling the conductive material constituting the gate electrode 130.

In this case, when the sacrificial insulating layer 130s is removed, a silicon oxynitride layer remaining around the tunnel portion TL of FIG. 8H that is not oxidized may be removed. When the first blocking layer 156a and/or the gate electrode 130 are formed, the first blocking layer 156a and/or the gate electrode 130 may be formed at a portion where the silicon oxynitride layer is removed. Accordingly, the insulating pattern 184i may have the structure shown in the enlarged view of FIG. 7.

According to an embodiment, an opening may be formed to expose the horizontal insulating layer 116. In an etching process through the opening, at least a portion of the horizontal insulating layer 116 and a portion of the gate dielectric layer 150 may be removed, and a material constituting the first horizontal conductive layer 112 may be filled to form the first horizontal conductive layer 112.

In addition, the separation structure 146 may be formed by filling the opening with an insulating material.

Subsequently, the vertical sacrificial layer 183c of FIG. 8H and a portion of the preliminary insulating layer 184j of FIG. 8H may be removed, and a conductive material may be filled to form the gate contact portion 184.

More specifically, after the vertical sacrificial layer 183c is selectively removed, the portion of the preliminary insulating layer 184j may be removed. In this case, all of the preliminary insulating layer 184j formed at the pad portion PP of the connection gate electrode 130c may be removed, and the preliminary insulating layer 184j formed at the tunnel portion TL of the remaining gate electrode 130r may remain to form the insulating pattern 184i.

Subsequently, a conductive material may be deposited within the wire penetrating portion OH to form the gate contact portion 184. The gate contact portion 184 may include the connection portion 184c protruding toward an inner surface of the pad portion PP. Thereafter, the second wire portion 180 connected to the channel structure CH may be further formed.

According to an embodiment, the semiconductor device 10 including the boundary insulating pattern 132p to effectively prevent a problem that could be caused by a falling out or a misalignment of the gate contact portion 184 may be manufactured through a simple process.

Hereinafter, a semiconductor device according to a different embodiment from the embodiment described above will be described in more detail with reference to FIGS. 9 to 14. A detailed description of a portion identical to or extremely similar to the portion already described will not be repeated, and only another portion will be described in detail.

FIG. 9 is an enlarged view of a portion of a lower structure of the semiconductor device according to another embodiment. FIG. 9 shows a portion corresponding to that shown in FIG. 6 (a).

Referring to FIG. 9, in an embodiment, the boundary insulating pattern 132p may have a line shape or a bar shape extending in an extending direction of the boundary gate electrode 130p. Accordingly, the boundary insulating pattern 132p may be formed to have a sufficient area, so that the boundary insulating pattern 132p may more effectively cope with a misalignment of the gate contact portion 184. For example, the boundary insulating pattern 132p may be formed to contact at least one dummy structure DH or surround the at least one dummy structure DH. The boundary insulating pattern 132p may be distinguished from the insulating pattern 184i of the gate contact portion 184 by this shape.

In this case, since the electrical connection path EP is provided at both sides of the boundary insulating pattern 132p in a width direction (an X-axis direction in the drawings) of the boundary gate electrode 130p, electrical connection may be maintained even if the boundary insulating pattern 132p is provided.

FIG. 10 is an enlarged view of a portion of a lower structure of the semiconductor device according to another embodiment. FIG. 10 shows a portion corresponding to one pad area PA of FIG. 5.

Referring to FIG. 10, in an embodiment, the boundary insulating pattern 132p may have a line shape or a bar shape extending in an extending direction of the boundary gate electrode 130p, and may have a shape surrounding the plurality of gate contact portions 184. Accordingly, the boundary insulating pattern 132p may be formed to have a sufficient area, such that the boundary insulating pattern 132p may cope more effectively with a misalignment of the gate contact portion 184. For example, the boundary insulating pattern 132p may be formed to surround the at least one dummy structure DH. The boundary insulating pattern 132p may be distinguished from the insulating pattern 184i of the gate contact portion 184 by this shape.

Thus, even when the boundary insulating pattern 132p has a shape surrounding the plurality of gate contact portions 184, the electrical connection path EP may be provided at both sides of the boundary insulating pattern 132p in a width direction of the boundary gate electrode 130p. Therefore, even if the boundary insulating pattern 132p is provided, electrical connection may be maintained.

Although it is illustrated that the boundary insulating pattern 132p is entirely formed to correspond to one pad area PA, the boundary insulating pattern 132p may be formed to correspond to a portion of the plurality of gate contact portions 184 disposed within the one pad area PA.

FIG. 11 is a partial cross-sectional view of the semiconductor device according to another embodiment.

Referring to FIG. 11, one boundary gate electrode 130p at which the boundary insulating pattern 132p is formed may be provided. Only one boundary gate electrode 130p may be provided to stably maintain the electrical connection path. That is, although FIG. 2 illustrates that the boundary insulating pattern 132p is formed over the plurality of boundary gate electrodes 130p, the embodiment is not limited thereto.

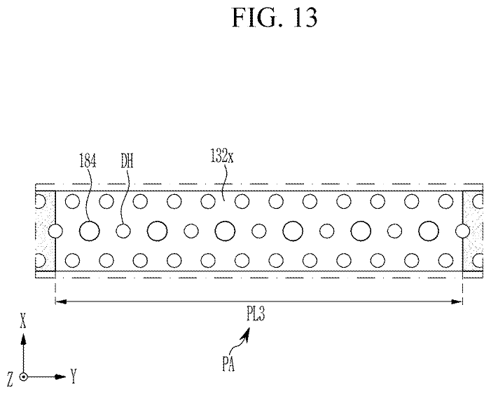

FIG. 12 is a partial cross-sectional view of the semiconductor device according to another embodiment, and FIG. 13 is a partial plan view illustrating an upper surface of the second gate stacking structure in the third lower pad area of the semiconductor device shown in FIG. 12.

Referring to FIGS. 12 and 13, in an embodiment, the boundary insulating pattern 132p may be disposed at the boundary gate electrode 130p adjacent to the boundary portion 120p of the second and third gate stacking structures 120b and 120c in the first upper pad area PU1. More specifically, the boundary insulating pattern 132p may be formed at the boundary gate electrode 130p disposed at the second gate stacking structure 120b that is a lower structure of the second and third gate stacking structures 120b and 120c.

In the first upper pad area PU1, the boundary gate electrode 130p of the second gate stacking structure 120b is a portion in which the electrical connection path has to be maintained by being disposed between the cell array region 102 and the second upper pad area PU2. Accordingly, a problem caused by falling out or misalignment of the gate contact portion 184 may be effectively prevented by providing the boundary insulating pattern 132p that does not interfere with the electrical connection path.

On the other hand, a cutting insulating pattern 132x may be provided at the gate electrode 130 of the second gate stacking structure 120b in the third lower pad area PL3. As shown in FIG. 13, in the cutting insulating pattern 132x, an entire region of the gate electrode 130 corresponding to the pad area PA may have a cut shape when the cutting insulating pattern 132x is viewed in a plan view. The inside of the cutting insulating pattern 132x may be filled with an insulating material such as a material of the pad insulating portion 132i or the like.

The cutting insulating pattern 132x may be formed by entirely removing a portion corresponding to the pad area PA in one or more gate electrodes 130 adjacent to the boundary portion 120p. In a case in which the cutting insulating pattern 132x is formed at the plurality of gate electrodes 130, as shown in FIG. 12, the cutting insulating pattern 132x may have a stair shape when the cutting insulating pattern 132x is viewed in a cross-section. However, the embodiment is not limited to a cross-sectional shape of the cutting insulating pattern 132x.

When the gate electrode 130 is cut and the pad insulating portion 132i covering the recess porting RP is formed in a process of forming the recess portion RP, the cutting insulating pattern 132x may be formed by filling an insulating material, as a non-limiting example. Accordingly, the cutting insulating pattern 132x may be formed by a separate process from the recess portion RP and the pad insulating portion 132i. For example, the cutting insulating pattern 132x may be formed as a portion of the upper insulating layer 132b. Other variations are possible.

The number of gate electrodes 130 including the cutting insulating pattern 132x may be equal to the number of boundary gate electrodes 130p at which the boundary insulating pattern 132p is formed. The number of gate electrodes 130 including the cutting insulating pattern 132x may be greater than or less than the number of boundary gate electrodes 130p at which the boundary insulating pattern 132p is formed. This is because the gate electrode 130 disposed at the second gate stacking structure 120b in the third lower pad area PL3 is not used as the electrical connection path and the cutting insulating pattern 132x is formed. The upper portion of the gate contact portion 184 penetrating the third gate stacking structure 120c in the third lower pad area PL3 may be formed within the pad insulating portion 132i to have a width that is relatively larger than that of another portion of the gate contact portion 184. If the boundary insulating pattern 132p is formed at the boundary gate electrode 130p of the second gate stacking structure 120b disposed below the upper portion of the gate contact portion 184, a problem that could be caused by a falling out or misalignment of the gate contact portion 184 may be more effectively prevented.

In the embodiment, insulating structures with different structures may be formed at a portion where the electrical connection path has to be maintained and a portion where the electrical connection path does not have to be maintained. According to an embodiment, if a disposition of the pad area PA has a different structure, a disposition of a portion where the electrical connection path is maintained and a disposition of a portion where the electrical connection path does not need to be maintained may be changed. In this case, positions of the boundary insulating pattern 132p and the cutting insulating pattern 132x may be changed, and such changes may also fall within a scope of the embodiment.

FIG. 12 illustrates that the boundary insulating pattern 132p and the cutting insulating pattern 132x are disposed at the second gate stacking structure 120b, but the boundary insulating pattern 132p and the cutting insulating pattern 132x may be disposed at different gate stacking structures. In addition, positions of the boundary insulating pattern 132p and the cutting insulating pattern 132x may be variously modified.

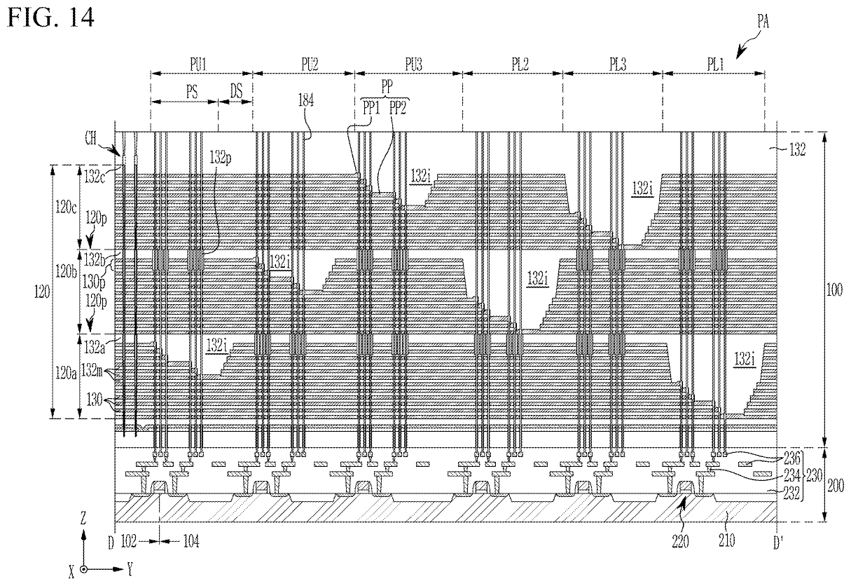

FIG. 14 is a partial cross-sectional view of the semiconductor device according to another embodiment.

Referring to FIG. 14, in an embodiment, the boundary insulating patterns 132p may be respectively formed at lower structures in all pad areas PA. This is because the boundary insulating pattern 132p may be freely formed in all pad areas PA since the electrical connection path is maintained.

That is, the boundary insulating pattern 132p may be formed at an upper portion of the second gate stacking structure 120b adjacent to the boundary portion 120p in the first upper pad area PU1. In addition, the boundary insulating pattern 132p may be formed at an upper portion of the first gate stacking structure 120a adjacent to the boundary portion 120p in the second upper pad area PU2. In addition, the boundary insulating pattern 132p may be formed at an upper portion of each of the first and second gate stacking structures 120a and 120b adjacent to the boundary portion 120p in the third upper pad area PU3. In addition, the boundary insulating pattern 132p may be formed at the upper portion of the first gate stacking structure 120a adjacent to the boundary portion 120p in the second lower pad area PL2. In addition, the boundary insulating pattern 132p may be formed at the upper portion of each of the first and second gate stacking structures 120a and 120b adjacent to the boundary portion 120p in the third lower pad area PL3. In addition, the boundary insulating pattern 132p may be formed at the upper portion of the second gate stacking structure 120b adjacent to the boundary portion 120p in the first lower pad area PL1, as non-limiting examples.

At least one boundary insulating pattern 132p may be formed at an upper portion of the first and/or second gate stacking structures 120a and 120b adjacent to the boundary portion 120p in one or more pad areas PA. That is, the boundary insulating pattern 132p may be formed to correspond to at least one pad area PA in the upper portion of the first gate stacking structure 120a adjacent to the boundary portion 120p. In some implementations, the boundary insulating pattern 132p may be formed to correspond to the at least one pad area PA in the upper portion of the second gate stacking structure 120b adjacent to the boundary portion 120p. Alternatively, the boundary insulating pattern 132p may be formed to correspond to the at least one pad area PA in the upper portion of the first gate stacking structure 120a adjacent to the boundary portion 120p, and the boundary insulating pattern 132p may be formed to correspond to the at least one pad area PA in the upper portion of the second gate stacking structure 120b adjacent to the boundary portion 120p. Other variations are possible. According to an embodiment, the cutting insulating pattern 132x provided in FIGS. 12 and 13 may be provided together with the boundary insulating pattern 132p. Thus, the embodiment is not limited to formation positions, the number of formations, or the like of the boundary insulating patterns 132p.

In the above-described embodiment, a case in which the gate stacking structure 120 includes three gate stacking structures 120a, 120b, and 120c has been mainly described, as non-limiting examples. Even when the gate stacking structure 120 includes two gate stacking structures or four or more gate stacked structures, the boundary insulating pattern 132p may be provided at the lower structure.

An additional embodiment that is different from the above-described embodiment will be described in detail here with reference to FIG. 15. Descriptions with reference to FIGS. 1 to 14 may be applied to FIG. 15 except for a case where reference numerals identical or similar to those of FIGS. 1 to 14 are differently mentioned. Hereinafter, a different portion from the portion described in the embodiments referring to FIGS. 1 to 14 will be mainly described.

FIG. 15 is a partial cross-sectional view schematically illustrating the semiconductor device according to the additional embodiment.

Referring to FIG. 15, the semiconductor device according to the embodiment may have a chip-to-chip (C2C) structure bonded by a wafer bonding method. That is, a lower chip including the circuit region 200a formed above or on a first substrate 210a may be manufactured, an upper chip including a cell region 100a formed above or on a second substrate 110a may be manufactured, and then the semiconductor device may be manufactured by bonding the lower chip and the upper chip.

The circuit region 200a may include the first substrate 210a, the circuit element 220, and a first bonding structure (or a first junction structure) 238 at a surface facing the cell region 100a above or on the first wire portion 230.

The cell region 100a may include the second substrate 110a, the gate stacking structure 120, the channel structure CH, and the second bonding structure 194 at a surface facing the circuit region 200a above or on the second wire portion 180.

The second substrate 110a may be a semiconductor substrate including a semiconductor material. For example, the second substrate 110a may be a semiconductor substrate made of a semiconductor material or may be a semiconductor substrate in which a semiconductor layer is formed on a base substrate. For example, the second substrate 110a may include a monocrystalline or polycrystalline silicon, germanium, silicon-germanium, a silicon-on-insulator, a germanium-on-insulator, or the like.

In the gate stacking structure 120, the gate electrode 130 may include the lower gate electrode, the memory cell gate electrode, and the upper gate electrode sequentially disposed from the second substrate 110a toward the circuit region 200a. As shown in FIG. 15, the gate stacking structure 120 may be stacked below the second substrate 110a so that the gate stacked structure 120 may be disposed in a shape in which the gate stacking structure 120 shown in FIGS. 1 to 3 may be disposed in a vertically inverted manner.

Accordingly, the channel pad 144 and the second wire portion 180 disposed above or on the gate stacking structure 120 may be disposed adjacent to the circuit region 200a. In addition, the second bonding structure 194 electrically connected to the second wire portion 180 may be provided at the surface facing the circuit region 200a. A region other than the second bonding structure 194 may be covered by the insulating layer 196. Thus, the second wire portion 180 and the second bonding structure 194 may be disposed in the cell region 100a to face the circuit region 200a.

For example, the first bonding structure 238 and/or the second bonding structure 194 may be made of aluminum, copper, tungsten, or an alloy including aluminum, copper, and tungsten. For example, the first and second bonding structures 238 and 194 may include copper so that the cell region 100a and the circuit region 200a may be bonded (e.g., bonded directly in contact with each other) by copper-to-copper bonding.

Although FIG. 15 illustrates that the gate stacking structure 120 includes the first to third stacking structures 120a, 120b, and 120c as shown in FIG. 2, the embodiment is not limited thereto. Except for cases described separately, the description of the gate stacking structure 120 and the channel structure CH described with reference to FIGS. 1 to 14 may be applied to FIG. 15. FIG. 15 illustrates that an electrical connection structure between the channel structure CH, the horizontal conductive layers 112 and 114, and/or the second substrate 110 is the same as that of FIG. 1. The embodiment is not limited thereto, and the electrical connection structure between the channel structure CH, the horizontal conductive layers 112 and 114, and/or the second substrate 110 may be variously modified.

The semiconductor device 10 according to an embodiment may include an input/output pad (not shown) and an input/output connection wire (not shown) electrically connected to the input/output pad. The input/output connection wire may be electrically connected to a portion of the second bonding structure 194. For example, the input/output pad may be disposed above or on an insulating layer 198b covering an outer surface of the second substrate 110a. According to an embodiment, a separate input/output pad electrically connected to the circuit region 200a may be provided.

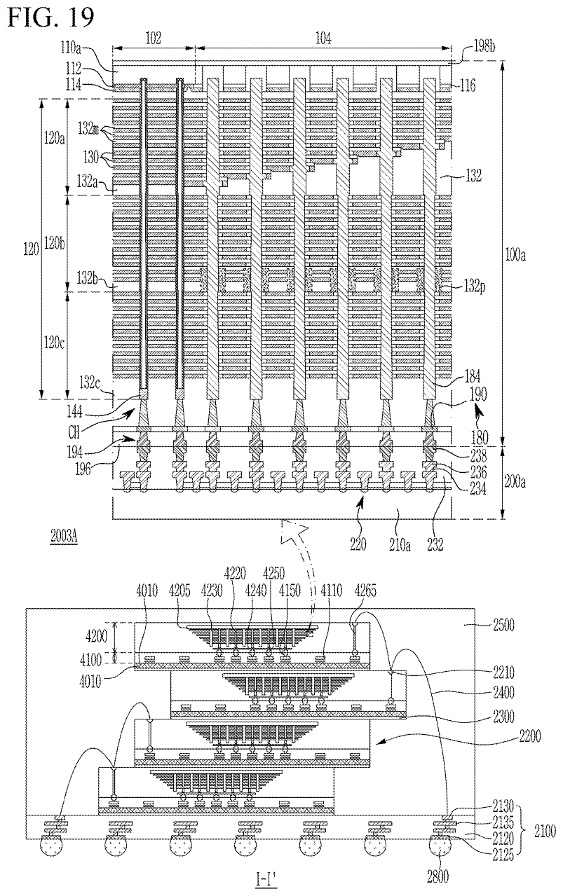

For example, the circuit region 200a and the cell region 100a may be portions corresponding to the first structure 1100F and the second structure 1100S of the semiconductor device 1100 included in the electronic system 1000 shown in FIG. 16, respectively. In some implementations, the circuit region 200a and the cell region 100a may be regions including a first structure 4100 and a second structure 4200 of a semiconductor chip 2200 shown in FIG. 19, respectively.

An example of an electronic system including the above-described semiconductor device will be described in detail below.

FIG. 16 is a view schematically illustrating the electronic system including the semiconductor device according to an embodiment.

Referring to FIG. 16, the electronic system 1000 according to the embodiment may include the semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid-state drive (SSD) device including one or a plurality of semiconductor devices 1100, a Universal Serial Bus (USB), a computing system, a medical device, or a communication device.

The semiconductor device 1100 may be a non-volatile memory device, and for example, may be a NAND flash memory device described with reference to FIGS. 1 to 15. The semiconductor device 1100 may include the first structure 1100F and the second structure 1100S on the first structure 1100F. In an embodiment, the first structure 1100F may be disposed next to the second structure 1100S. The first structure 1100F may be a peripheral circuit structure including the decoder circuit 1110, the page buffer 1120, and the logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously modified according to an embodiment.

In an embodiment, the lower transistors LT1 and LT2 may include a ground selection transistor, and the upper transistors UT1 and UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wire 1115 extending to the second structure 1100S within the first structure 1100F. The bit line BL may be electrically connected to the page buffer 1120 through a second connection wire 1125 extending to the second structure 1100S within the first structure 1100F.

In the first structure 1100F, the decoder circuit 1110 and the page buffer 1120 may execute a control operation for at least one memory cell transistor selected from among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 extending to the second structure 1100S within the first structure 1100F.

The controller 1200 may include a processor 1210, a NAND controller 1220, and a host interface 1230. According to an embodiment, the electronic system 1000 may include the plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

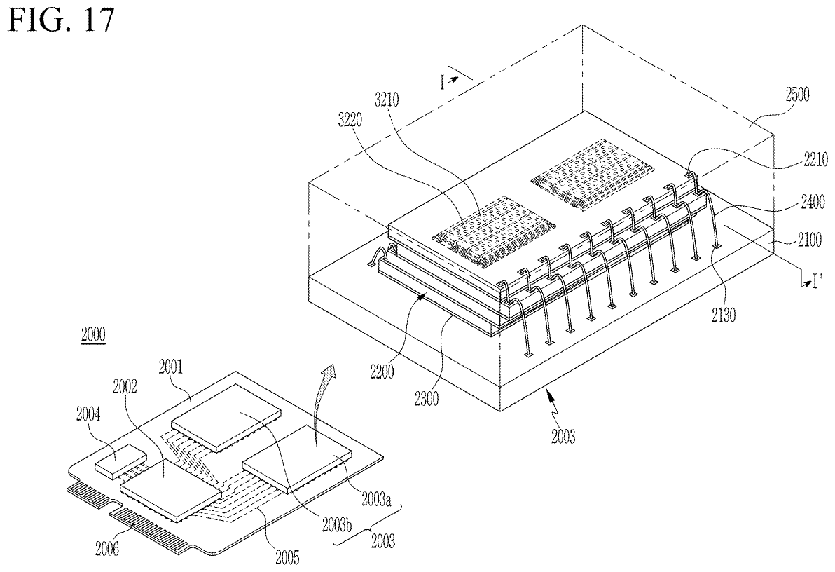

FIG. 17 is a schematic perspective view of an electronic system including the semiconductor device according to an embodiment.

Referring to FIG. 17, the electronic system 2000 according to the embodiment may include a main substrate 2001, a controller 2002 mounted on the main substrate 2001, one or more semiconductor packages 2003, and a DRAM 2004. The semiconductor package 2003 and the DRAM 2004 may be connected to the controller 2002 through a wire pattern 2005 formed at the main substrate 2001.

The main substrate 2001 may include a connector 2006 including a plurality of pins coupled to the external host. The number and a disposition of the plurality of pins in the connector 2006 may vary depending on a communication interface between the electronic system 2000 and the external host. In an embodiment, the electronic system 2000 may communicate with the external host according to any one of interfaces such as a universal serial bus (USB), a peripheral component interconnect express (PCI-Express), a serial advanced technology attachment (SATA), and an M-Phy for a universal flash storage (UFS). In an embodiment, the electronic system 2000 may operate with a power supply supplied from the external host through the connector 2006. The electronic system 2000 may further include a power management integrated circuit (PMIC) that distributes the power supply supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating a speed difference between the semiconductor package 2003, which is a data storage space, and the external host. The DRAM 2004 included in the electronic system 2000 may also operate as a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chip 2200 above or on the package substrate 2100, an adhesive layer 2300 disposed at a lower surface of each semiconductor chip 2200, a connection structure 2400 electrically connecting the semiconductor chip 2200 and the package substrate 2100, and a molding layer 2500 covering the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 16. Each semiconductor chip 2200 may include a gate stacking structure 3210 and a channel structure 3220. The semiconductor chip 2200 may include the semiconductor devices described with reference to FIGS. 1 to 15.

In an embodiment, the connection structure 2400 may be a bonding wire electrically connecting the input/output pad 2210 and the package upper pad 2130. Accordingly, in each of the first and second semiconductor packages 2003a and 2003b, the semiconductor chips 2200 may be electrically connected to each other using a bonding wire method, and the semiconductor chip 2200 may be electrically connected to the package upper pad 2130 of the package substrate 2100. According to an embodiment, in each of the first and second semiconductor packages 2003a and 2003b, the semiconductor chips 2200 may be electrically connected to each other by a connection structure including a through silicon via (TSV) instead of the connection structure 2400 using a bonding wire method.

In an embodiment, the controller 2002 and the semiconductor chip 2200 may be included in one package. For example, the controller 2002 and the semiconductor chip 2200 may be mounted at a separate interposer substrate that is different from the main substrate 2001, and the controller 2002 and the semiconductor chip 2200 may be connected to each other by a wire formed at the interposer substrate.

FIGS. 18 and 19 are cross-sectional views schematically illustrating semiconductor packages according to embodiments, respectively. FIGS. 18 and 19 respectively describe the embodiment of the semiconductor package 2003 of FIG. 17, and conceptually show a region obtained by cutting the semiconductor package 2003 of FIG. 17 along a line I-I′.

Referring to FIG. 18, in the semiconductor package 2003, the package substrate 2100 may be a printed circuit board. The package substrate 2100 may include a package substrate body portion 2120, the package upper pad 2130 disposed at an upper surface of the package substrate body portion 2120, a lower pad 2125 disposed at a lower surface of the package substrate body portion 2120 or exposed through the lower surface of the package substrate body portion 2120, and an internal wire 2135 electrically connecting the upper pad 2130 and the lower pad 2125 inside the package substrate body portion 2120. The upper pad 2130 may be electrically connected to the connection structure 2400. The lower pad 2125 may be connected to the wire pattern 2005 of the main substrate 2001 of the electronic system 2000 of FIG. 17 through a conductive connection portion 2800.

The semiconductor chip 2200 may include a semiconductor substrate 3010 and the first structure 3100 and the second structure 3200 sequentially stacked on the semiconductor substrate 3010. The first structure 3100 may include a peripheral circuit region including a peripheral wire 3110. The second structure 3200 may include a common source line 3205, the gate stacking structure 3210 on the common source line 3205, the channel structure 3220 and a separation structure 3230 penetrating the gate stacking structure 3210, a bit line 3240 electrically connected to the channel structure 3220, and a gate connection wire electrically connected to the word line WL of FIG. 16 of the gate stacking structure 3210.

In the semiconductor chip 2200 or the semiconductor device according to an embodiment, a problem that could be caused by a falling out or a misalignment of the gate contact portion 184 may be effectively prevented by providing the boundary insulating pattern 132p.

Each of the semiconductor chips 2200 may include a through wire 3245 that is electrically connected to the peripheral wire 3110 of the first structure 3100 and extends into the second structure 3200. The through wire 3245 may pass through the gate stacking structure 3210, and may be further disposed outside the gate stacking structure 3210. Each semiconductor chip 2200 may further include an input/output connection wire 3265 electrically connected to the peripheral wire 3110 of the first structure 3100 and extending into the second structure 3200, and the input/output pad 2210 electrically connected to the input/output connection wire 3265.

In an embodiment, in the semiconductor package 2003, the plurality of semiconductor chips 2200 may be electrically connected to each other by the connection structure 2400 having a bonding wire form. As another example, the plurality of semiconductor chips 2200 or a plurality of portions constituting the semiconductor chips 2200 may be electrically connected by a connection structure including a through silicon via (TSV).

Referring to FIG. 19, in a semiconductor package 2003A, each semiconductor chip 2200 may include a semiconductor substrate 4010, a first structure 4100 on the semiconductor substrate 4010, and the second structure 4200 bonded to the first structure 4100 by a wafer bonding method on the first structure 4100.

The first structure 4100 may include a peripheral circuit region including a peripheral wire 4110 and a first bonding structure 4150. The second structure 4200 may include a common source line 4205, a gate stacking structure 4210 between the common source line 4205 and the first structure 4100, a channel structure 4220 and a separation structure 4230 passing through the gate stacking structure 4210, and a second bonding structure 4250 electrically connected to the channel structure 4220 and the word line WL of FIG. 16 of the gate stacking structure 4210. For example, the second bonding structure 4250 may be electrically connected to the channel structure 4220 and the word line WL through a bit line 4240 electrically connected to the channel structure 4220 and the gate connection wire electrically connected to the word line WL. The first bonding structure 4150 of the first structure 4100 and the second bonding structure 4250 of the second structure 4200 may be bonded while contacting each other. For example, a portion where the first bonding structure 4150 and the second bonding structure 4250 are bonded may be formed of copper (Cu).

In the semiconductor chip 2200 or the semiconductor device according to an embodiment, a problem that could be caused by a falling out or misalignment of the gate contact portion 184 may be effectively prevented by providing the boundary insulating pattern 132p.

Each of the semiconductor chips 2200 may further include the input/output pad 2210 and an input/output connection wire 4265 below the input/output pad 2210. The input/output connection wire 4265 may be electrically connected to a portion of the second bonding structure 4250.

In an embodiment, in the semiconductor package 2003, the plurality of semiconductor chips 2200 may be electrically connected to each other by the connection structure 2400 having a bonding wire form. As another example, the plurality of semiconductor chips 2200 or a plurality of portions constituting the semiconductor chips 2200 may be electrically connected by a connection structure including a through silicon via (TSV).

By way of summation and review, embodiments provide a semiconductor device capable of storing high-capacity data and an electronic system that is capable of improving productivity and reliability

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device comprising:
a first substrate:
a circuit region including a peripheral circuit structure on the first substrate; and
a cell region that is disposed on the circuit region and includes a cell array region and a connection region,
wherein the cell region includes:
a second substrate;
a gate stacking structure that is on the second substrate and includes a lower structure and an upper structure, the lower structure and the upper structure each including a plurality of gate electrodes;
a channel structure penetrating the gate stacking structure;
a gate contact portion that penetrates the gate stacking structure and is electrically connected to the circuit region, is electrically connected to a connection gate electrode among the plurality of gate electrodes, and is insulated from a remaining gate electrode by an insulating pattern between the remaining gate electrode and the gate contact portion; and
a boundary insulating pattern that is partially in a boundary gate electrode among the plurality of gate electrodes of the lower structure adjacent to a boundary portion between the upper structure and the lower structure to surround the gate contact portion to maintain an electrical connection path of the boundary gate electrode and has a different structure from that of the insulating pattern.

2. The semiconductor device as claimed in claim 1, wherein as viewed in a plan view, the boundary insulating pattern has a closed shape that does not cut the boundary gate electrode.

3. The semiconductor device as claimed in claim 2, wherein as viewed in a plan view, the boundary insulating pattern has a circular, polygonal, or line shape.

4. The semiconductor device as claimed in claim 1, wherein, in a width direction of the boundary gate electrode, a width of the boundary insulating pattern is greater than a width of the gate contact portion and is less than a width of the boundary gate electrode.

5. The semiconductor device as claimed in claim 1, wherein the boundary gate electrode at which the boundary insulating pattern is formed includes one or more boundary gate electrodes.

6. The semiconductor device as claimed in claim 1, wherein the boundary insulating pattern and the insulating pattern are made of different materials.

7. The semiconductor device as claimed in claim 6, wherein:
the boundary insulating pattern includes an insulating material of a single composition, and
the insulating pattern is formed of a plurality of insulating layers, or includes a step or a portion of a blocking layer or a portion of the gate electrode at an upper or lower surface of the insulating pattern.

8. The semiconductor device as claimed in claim 1, wherein when the boundary insulating pattern is viewed in a cross-section, an entire side surface of the boundary insulating pattern includes an inclined surface that gradually decreases in width toward the second substrate or that includes a vertical surface perpendicular to the second substrate.

9. The semiconductor device as claimed in claim 1, wherein a side surface of the insulating pattern has a slope that is smaller than a slope of the boundary insulating pattern, or includes a convex shape or a rounded portion.

10. The semiconductor device as claimed in claim 1, wherein:
the insulating pattern includes a void extending in a horizontal direction, and
the boundary insulating pattern does not include a void or includes a void extending in a vertical direction.

11. The semiconductor device as claimed in claim 1, wherein:
the boundary insulating pattern has a vertical etching and filling structure extending from an upper portion of the lower structure toward the second substrate, and
the insulating pattern has a horizontal etching structure etched in a horizontal direction and a horizontal filling structure filled in a horizontal direction.

12. The semiconductor device as claimed in claim 1, wherein:
the lower structure includes an upper insulating layer at the boundary portion bonded to the upper structure, and
the boundary insulating pattern extends from an upper surface of the upper insulating layer to pass through the boundary gate electrode.

13. The semiconductor device as claimed in claim 1, wherein:
an entire width of the boundary insulating pattern is 100 nm to 1,000 nm; or
a peripheral width of the boundary insulating pattern from an outer edge of the gate contact portion is 1 nm to 300 nm; or
an entire depth of the boundary insulating pattern is 1 nm to 1,000 nm.

14. The semiconductor device as claimed in claim 1, wherein an entire depth of the boundary insulating pattern is greater than a peripheral width of the boundary insulating pattern from an outer edge of the gate contact portion.

15. The semiconductor device as claimed in claim 1, wherein:
the boundary insulating pattern is at a portion where an electrical connection path must be maintained and
the boundary insulating pattern is between the cell array region and a pad area to which another gate contact portion is connected.

16. The semiconductor device as claimed in claim 1, wherein:
the semiconductor device includes a dummy structure penetrating the gate stacking structure in the connection region and the boundary insulating pattern is formed to surround the dummy structure along with the gate contact portion; or
the gate contact portion includes a plurality of gate contact portions, and the boundary insulating pattern is formed to surround the plurality of gate contact portions.

17. The semiconductor device as claimed in claim 1, further comprising a cutting insulating pattern that is formed to cut at least one gate electrode among a plurality of gate electrodes corresponding to a pad area to which another gate contact portion different from the gate contact portion is connected.

18. The semiconductor device as claimed in claim 1, wherein:
the gate stacking structure includes a first gate stacking structure disposed on the second substrate, a second gate stacking structure disposed on the first gate stacking structure to from the lower structure, and a third gate stacking structure disposed on the second gate stacking structure to form the upper structure,
the connection region includes first, second, and third pad areas to which the first, second, and third gate stacking structures and the gate contact portion are connected, respectively,
the first, second, and third pad areas are sequentially disposed in a direction away from the cell array region, and
the boundary insulating pattern is formed at the boundary gate electrode of the second gate stacking structure adjacent to a boundary portion between the third gate stack structure and the second gate stacking structure in the first pad area.

19. A semiconductor device comprising:
a first substrate;
a circuit region including a peripheral circuit structure on the first substrate; and
a cell region that is on the circuit region and includes a cell array region and a connection region,
wherein the cell region includes:
a second substrate;
a gate stacking structure that is on the second substrate and includes a lower structure and an upper structure, wherein the lower structure and the upper structure each include a plurality of gate electrodes;
a channel structure penetrating the gate stacking structure;
a gate contact portion that penetrates the gate stacking structure to be electrically connected to the circuit region; and
a boundary insulating pattern that is partially formed in a boundary gate electrode among the plurality of gate electrodes of the lower structure adjacent to a boundary portion between the upper structure and the lower structure to surround the gate contact portion to maintain an electrical connection path of the boundary gate electrode; and
wherein an entire side surface of the boundary insulating pattern includes an inclined surface that gradually decreases in width toward the second substrate or a vertical surface perpendicular to the second substrate when the boundary insulating pattern is viewed in a cross-section.

20. An electronic system. comprising:
a main substrate;
a semiconductor device on the main substrate; and
a controller electrically connected to the semiconductor device on the main substrate,
wherein the semiconductor device includes a circuit region including a peripheral circuit structure on a first substrate and a cell region that is disposed on the circuit region and includes a cell array region and a connection region, and
wherein the cell region includes:
a second substrate;
a gate stacking structure that is on the second substrate and includes a lower structure and an upper structure, wherein the lower structure and the upper structure each include a plurality of gate electrodes;
a channel structure penetrating the gate stacking structure;
a gate contact portion that penetrates the plurality of gate electrodes to be electrically connected to the circuit region, is electrically connected to a connection gate electrode among the plurality of gate electrodes, and is insulated from a remaining gate electrode by an insulating pattern that is disposed between the remaining gate electrode and the gate contact portion; and
a boundary insulating pattern that is partially formed in a boundary gate electrode among the plurality of gate electrodes of the lower structure adjacent to a boundary portion between the upper structure and the lower structure to surround the gate contact portion to maintain an electrical connection path of the boundary gate electrode and has a different structure from that of the insulating pattern.
